(19) United States
(12) Patent Application Publication
(10) Pub. No.: US 2017/0309852 A1
(43) Pub. Date: Oct. 26, 2017

(54) Light-Emitting Element, Display Device, Electronic Device, and Lighting Device

(71) Applicant: Semiconductor Energy Laboratory Co., Ltd., Kanagawa-ken (JP)

(72) Inventors: Satoshi SEO, Sagamihara (JP); Shogo UESAKA, lsehara (JP); Toshiki SASAKI, lsehara (JP); Nobuharu OHSAWA, Zama (JP)

(73) Assignee: Semiconductor Energy Laboratory Co., Ltd., Kanagawa-ken (JP)

(21) Appl. No.: 15/491,536

(22) Filed: Apr. 19, 2017

(30) Foreign Application Priority Data
Apr. 22, 2016 (JP) 2016-086490

(51) Int. Cl. H01L 51/50; H01L 51/52; H01L 27/32; H01L 51/00

(52) U.S. Cl. CPC H01L 51/5004; H01L 51/5206; H01L 51/5221; H01L 27/3262; H01L 51/5012; H01L 51/0072; H01L 51/0061; H01L 51/006; H01L 51/0058; H01L 51/0054; H01L 51/0052; H01L 51/0073; H01L 2251/301; H01L 2251/303; H01L 2251/552; H01L 2251/308

(57) ABSTRACT

To provide a light-emitting element with low drive voltage. The light-emitting element includes a first electrode, a second electrode, and an EL layer. The first electrode includes a first conductive layer and a second conductive layer including a region in contact with the first conductive layer. The first conductive layer has a function of reflecting light, and the second conductive layer has a function of transmitting light. The second conductive layer includes an oxide containing In and M (M represents one or more of Al, Si, Ti, Ga, Y, Zr, La, Ce, Nd, and Hf). The EL layer includes an organic acceptor material in a region in contact with the second conductive layer.

### BACKGROUND OF THE INVENTION

### 1. Field of the Invention

One embodiment of the present invention relates to a light-emitting element, or a display device, an electronic device, and a lighting device each including the light-emitting element.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, a method for driving any of them, and a method for manufacturing any of them.

### 2. Description of the Related Art

In recent years, research and development have been extensively conducted on light-emitting elements using electroluminescence (EL). In a basic structure of such a light-emitting element, a layer containing a light-emitting material (an EL layer) is interposed between a pair of electrodes. By application of a voltage between the electrodes of this element, light emission from the light-emitting material can be obtained.

Since the above light-emitting element is a self-luminous type, a display device using this light-emitting element has advantages such as high visibility, no necessity of a backlight, and low power consumption. Furthermore, the display device using the light-emitting element also has advantages in that it can be formed to be thin and lightweight, and has high response speed.

In order to improve the extraction efficiency of light from a light-emitting element, a method has been proposed, in which a micro optical resonator (microcavity) structure utilizing a resonant effect of light between a pair of electrodes is used to increase the intensity of light having a specific wavelength (e.g., see Patent Document 1).

Furthermore, in order to reduce power consumption of a light-emitting element, a method has been proposed, in which a metal oxide having a high work function is used for one of a pair of electrodes, through which light is not extracted, to reduce voltage loss due to the electrode and thus to reduce the drive voltage of a light-emitting element (e.g., see Patent Document 2).

In order to facilitate injection of carriers from an electrode to an EL layer, a method using an organic acceptor material has been proposed (e.g., see Patent Document 3).

### REFERENCE

### Patent Document

### [Patent Document 1] Japanese Published Patent Application No. 2012-182127

### [Patent Document 2] Japanese Published Patent Application No. 2012-182119

### [Patent Document 3] Japanese Translation of PCT International Application No. 2007-518220

### SUMMARY OF THE INVENTION

In order to improve light extraction efficiency of a light-emitting element, it is preferable to use a material having high reflectance for one of a pair of electrodes, through which light is not extracted. In addition, in order to reduce the drive voltage of a light-emitting element, it is preferable to use a material having a high work function for an anode. However, it is difficult to select a stable material which has high reflectance and a high work function and which is suitable for such an electrode of the light-emitting element.

For this reason, the structure of an electrode in which a material having high reflectance and a material having a high work function are stacked has been employed to achieve an improvement of light extraction efficiency of a light-emitting element and a reduction of its drive voltage. However, electrons might be donated and accepted at an interface between two stacked different kinds of materials because of a difference in ionization tendency. Moreover, oxygen might be donated and accepted at the interface between the two stacked different kinds of materials when an oxide is used as one of them. Such donation and acceptance of electrons or oxygen result in corrosion of the electrode materials. In some cases, a defect due to film separation, a decrease of emission efficiency, or an increase of drive voltage of the light-emitting element might be resulted from the corrosion of the electrode materials because it changes stress of an electrode formed using the electrode materials. Furthermore, these disadvantages also involve an electrical short circuit or a light-emission defect of the light-emitting element.

An energy barrier between an electrode and an EL layer causes problems of an increase in drive voltage of a light-emitting element and an increase in power consumption of the light-emitting element. For that reason, an energy barrier between an electrode and an EL layer is required to be reduced.

In view of the above-described problems, an object of one embodiment of the present invention is to provide a light-emitting element with low drive voltage. Another object of one embodiment of the present invention is to provide a light-emitting element with high emission efficiency. Another object of one embodiment of the present invention is to provide a light-emitting element with low power consumption. Another object of one embodiment of the present invention is to provide a novel light-emitting element. Another object of one embodiment of the present invention is to provide a novel display device.

Note that the description of the above objects does not disturb the existence of other objects. In one embodiment of the present invention, there is no need to achieve all the objects. Other objects are apparent from and can be derived from the description of the specification and the like.

One embodiment of the present invention is a light-emitting element including a first electrode, a second electrode, and an EL layer located between the first electrode and the second electrode. The first electrode includes a first conductive layer and a second conductive layer including a region in contact with the first conductive layer. The first conductive layer has a function of reflecting light and the second conductive layer has a function of transmitting light. The second conductive layer includes an oxide containing In and M (M represents one or more of Al, Si, Ti, Ga, Y, Zr, La, Ce, Nd, and Hf). The EL layer includes an organic acceptor material in a region in contact with the second conductive layer.

Another embodiment of the present invention is a light-emitting element including a first electrode, a second electrode, and an EL layer located between the first electrode and the second electrode. The first electrode includes a first conductive layer and a second conductive layer including a region in contact with the first conductive layer. The first conductive layer has a function of reflecting light and the second conductive layer has a function of transmitting light. The second conductive layer includes an oxide containing In and M (M represents one or more of Al, Si, Ti, Ga, Y, Zr, La, Ce, Nd, and Hf). The EL layer includes an organic acceptor material in a region in contact with the second conductive layer. A difference between the energy level of the conduction band minimum of the oxide and the energy level of LUMO of the organic acceptor material is greater than or equal to 0 eV and less than or equal to 0.5 eV.

In each of the above structures, the EL layer preferably includes an acceptor material different from the organic acceptor material in a region in contact with the region including the organic acceptor material.

Another embodiment of the present invention is a light-emitting element including a first electrode, a second electrode, and an EL layer located between the first electrode and the second electrode. The first electrode includes a first conductive layer and a second conductive layer including a region in contact with the first conductive layer. The first conductive layer has a function of reflecting light and the second conductive layer has a function of transmitting light. The second conductive layer includes an oxide containing In and M (M represents one or more of Al, Si, Ti, Ga, Y, Zr, La, Ce, Nd, and Hf). The EL layer includes a first region in contact with the second conductive layer and a second region in contact with the first region. The first region includes an organic acceptor material and the second region includes a hole-transport material. A difference between the energy level of the conduction band minimum of the oxide and the energy level of LUMO of the organic acceptor material is greater than or equal to 0 eV and less than or equal to 0.5 eV.

In the above structure, the second region preferably includes an acceptor material different from the organic acceptor material.

In each of the above structures, the organic acceptor material preferably has an azatriphenylene skeleton. The azatriphenylene skeleton preferably has 4 or more N atoms. The azatriphenylene skeleton preferably has 6 N atoms. The organic acceptor material preferably has a cyano group. The organic acceptor material preferably includes 2,3,6,7,10,11-hexacyano-1,4,5,8,9,12-hexaazatriphenylene.

In each of the above structures, the content of M is preferably higher than or equal to the content of In in the oxide. M is preferably Ga. The oxide preferably includes Zn. The oxide preferably includes In, Ga, and Zn.

In each of the above-described structures, the first conductive layer preferably contains Al or Ag.

In each of the above structures, the second electrode preferably contains at least one of In, Ag, and Mg.

Another embodiment of the present invention is a display device including the light-emitting element having any of the above-described structures and a transistor electrically connected to the first electrode or the second electrode.

In the above structure, the transistor preferably includes an oxide semiconductor layer in a channel region, and the oxide semiconductor layer contains In and M (M represents one or more of Al, Si, Ti, Ga, Y, Zr, La, Ce, Nd, and Hf). The second conductive layer and the oxide semiconductor layer preferably include the same element.

Another embodiment of the present invention is an electronic device including the display device having any of the above structures and at least one of a housing and a touch sensor. Another embodiment of the present invention is a lighting device including the light-emitting element having any of the above structures and at least one of a housing and a touch sensor. The category of one embodiment of the present invention includes not only the light-emitting device including the light-emitting element but also an electronic device including the light-emitting device. That is, the light-emitting device in this specification refers to an image display device or a light source (including a lighting device). A display module in which a connector such as a flexible printed circuit (FPC) or a tape carrier package (TCP) is connected to a light-emitting element, a display module in which a printed wiring board is provided on the tip of a TCP, and a display module in which an integrated circuit (IC) is directly mounted on a light-emitting element by a chip on glass (COG) method are also embodiments of the present invention.

With one embodiment of the present invention, a light-emitting element with low drive voltage can be provided. With one embodiment of the present invention, a light-emitting element with high emission efficiency can be provided. With one embodiment of the present invention, a light-emitting element with low power consumption can be provided. With one embodiment of the present invention, a novel light-emitting element can be provided. With one embodiment of the present invention, a novel display device can be provided.

Note that the description of these effects does not disturb the existence of other effects. One embodiment of the present invention does not necessarily have all the effects described above. Other effects will be apparent from and can be derived from the description of the specification, the drawings, the claims, and the like.

### BRIEF DESCRIPTION OF THE DRAWINGS

FIG. 1 is a schematic cross-sectional view illustrating a light-emitting element of one embodiment of the present invention.

FIG. 2 shows a correlation of energy levels in a light-emitting element of one embodiment of the present invention.

FIGS. 3A and 3B illustrate crystal models used for calculation of one embodiment of the present invention.

FIG. 4 is a schematic cross-sectional view of a light-emitting element of one embodiment of the present invention.

FIG. 5 is a schematic cross-sectional view of a light-emitting element of one embodiment of the present invention.

FIGS. 6A and 6B are schematic cross-sectional views each illustrating a light-emitting element of one embodiment of the present invention.

FIGS. 7A and 7B are a top view and a schematic cross-sectional view illustrating a display device of one embodiment of the present invention.

FIGS. 8A and 8B are each a schematic cross-sectional view illustrating a display device of one embodiment of the present invention.

FIGS. 9A and 9B are each a schematic cross-sectional view illustrating a display device of one embodiment of the present invention.

FIGS. 10A to 10G illustrate electronic devices of embodiments of the present invention.

FIGS. 11A to 11C are perspective views illustrating a display device of one embodiment of the present invention.

FIG. 12 illustrates a lighting device of one embodiment of the present invention.

FIG. 13 shows luminance-current density characteristics of light-emitting elements in Example.

FIG. 14 shows luminance-voltage characteristics of light-emitting elements in Example.

FIG. 15 shows current efficiency-luminance characteristics of light-emitting elements in Example.

FIG. 16 shows energy efficiency-luminance characteristics of light-emitting elements in Example.

FIG. 17 shows electroluminescence spectra of light-emitting elements in Example.

FIGS. 18A and 18B each show a correlation of energy levels in Example.

### DETAILED DESCRIPTION OF THE INVENTION

Embodiments of the present invention will be described below with reference to the drawings. However, the present invention is not limited to description to be given below, and it is easily understood that modes and details thereof can be variously modified without departing from the purpose and the scope of the present invention. Accordingly, the present invention should not be construed as being limited to the description of the embodiments below.

Note that the position, the size, the range, or the like of each structure shown in drawings and the like is not accurately represented in some cases for simplification. Therefore, the disclosed invention is not necessarily limited to the position, the size, the range, or the like disclosed in the drawings and the like.

Note that the ordinal numbers such as “first”, “second”, and the like in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those which specify one embodiment of the present invention.

In describing structures of the invention with reference to the drawings in this specification and the like, common reference numerals are used for the same portions in different drawings.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

### Embodiment 1

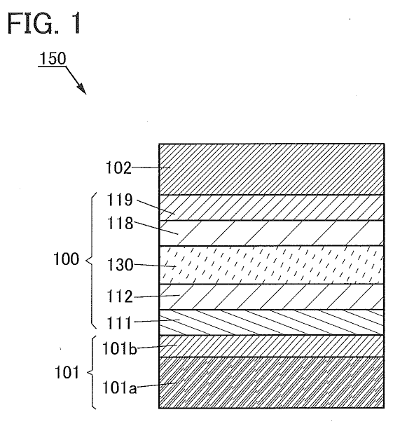

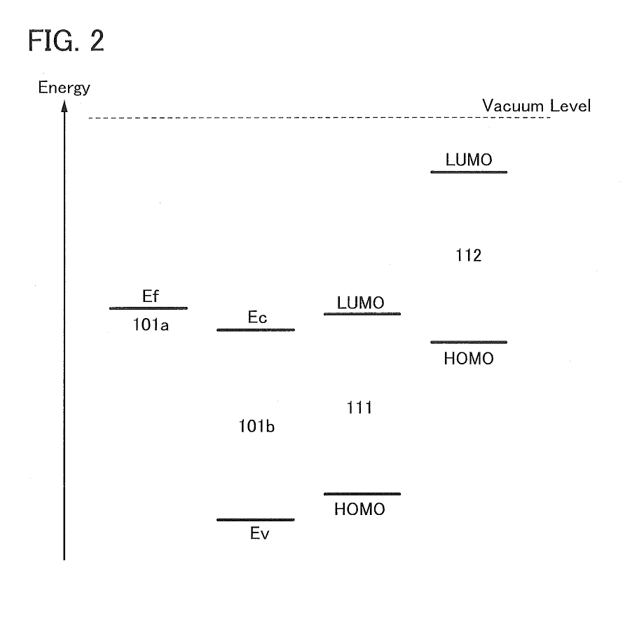

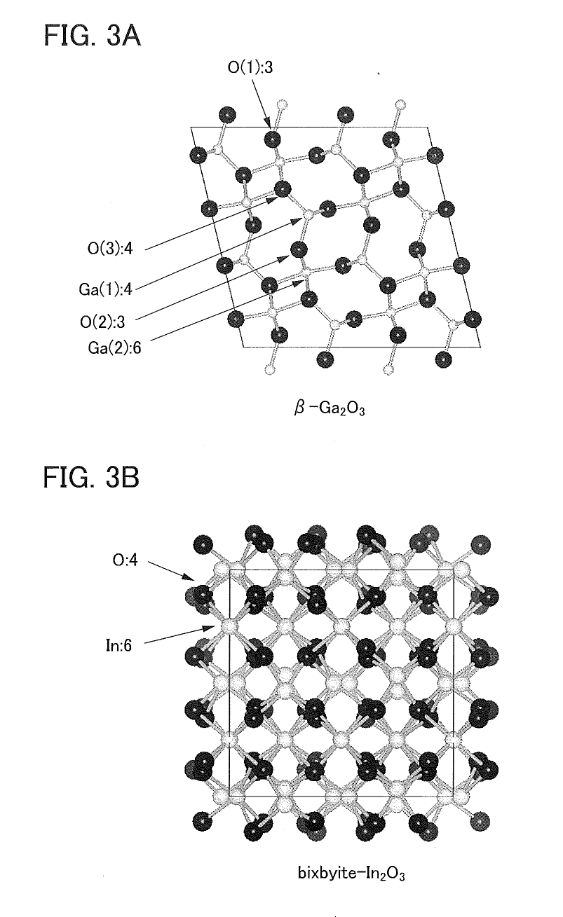

In this embodiment, a light-emitting element of one embodiment of the present invention will be described below with reference to FIG. 1, FIG. 2, and FIGS. 3A and 3B.

### <Structure Example of Light-Emitting Element>

FIG. 1 is a cross-sectional view illustrating a light-emitting element of one embodiment of the present invention. A light-emitting element 150 illustrated in FIG. 1 includes an electrode 101, an EL layer 100, and an electrode 102. The electrode 101 includes a conductive layer 101a and a conductive layer 101b over and in contact with the conductive layer 101a.

The EL layer 100 illustrated in FIG. 1 includes a hole-injection layer 111 in a region in contact with the conductive layer 101b. The EL layer 100 may further include a hole-transport layer 112, a light-emitting layer 130, an electron-transport layer 118, and an electron-injection layer 119.

Although the electrode 101 is an anode and the electrode 102 is a cathode in the light-emitting element of this embodiment, the structure of the light-emitting element is not limited thereto. That is, the stacking order of the layers between the electrodes may be reversed assuming that the electrode 101 is a cathode and the electrode 102 is an anode. In other words, the hole-injection layer 111, the hole-transport layer 112, the light-emitting layer 130, the electron-transport layer 118, and the electron-injection layer 119 may be stacked in this order from the anode side.

These layers may be formed in the EL layer between the pair of electrodes, depending on their functions, and are not limited to the above layers. In other words, the EL layer between the pair of electrodes may include a layer which has a function of reducing a barrier to hole or electron injection, enhancing a hole/electron-transport property, inhibiting a hole/electron transport property, suppressing a quenching phenomenon due to an electrode, or the like.

The conductive layer 101a of the electrode 101 has a function of reflecting light. When the conductive layer 101a is formed using a material containing a metal having favorable reflectance, e.g., aluminum (Al) or silver (Ag), the reflectance of the conductive layer 101a can be increased and the emission efficiency of the light-emitting element 150 can be increased. Note that Al is preferable because material cost is low, patterning can be easily performed, and manufacturing cost of a light-emitting element can be reduced. In addition, Ag is preferable because its particularly high reflectance can increase the emission efficiency of a light-emitting element.

In addition, in the case where the electrode 101 is used as an anode, a region of the electrode 101 that is in contact with the EL layer 100 preferably has a high work function. Accordingly, a hole-injection property from the electrode 101 to the EL layer 100 can be improved. However, it is difficult to select a stable material which has high reflectance and a high work function and which is suitable for an electrode of a light-emitting element. This is because with Al and Ag, surface oxidation easily occurs in the air and a metal oxide film is formed on the surfaces of Al and Ag. When the resistivity of the metal oxide film is high, the resistivity of the electrode 101 also becomes high; as a result, the hole-injection property from the electrode 101 to the EL layer 100 deteriorates and the drive voltage of the light-emitting element 150 increases. Thus, the electrode 101 preferably has a structure where the conductive layer 101b is provided over and in contact with the conductive layer 101a. A material having a high work function is preferably used for the conductive layer 101b.

The conductive layer 101b which is over and in contact with the conductive layer 101a preferably has a function of transmitting light and preferably has high transmittance. When the conductive layer 101b has a function of transmitting visible light, the electrode 101 can have high reflectance and thus the light-emitting element 150 can have high emission efficiency.

In addition, the conductive layer 101b is preferably formed using an oxide, and in particular, an oxide containing indium (In) is preferably used. When the conductive layer 101b contains In, the conductivity of the conductive layer 101b can be increased and the drive voltage of the light-emitting element 150 can be reduced. In addition, the light transmittance of the conductive layer 101b can be increased; thus, the emission efficiency of the light-emitting element 150 can be increased. In addition, with an oxide containing In, the hole-injection property from the conductive layer 101b to the EL layer 100 can be improved because of a high work function of the oxide, and the drive voltage of the light-emitting element 150 can be reduced.

The conductive layer 101b has conductivity, and the resistivity of the conductive layer 101b is preferably lower than or equal to 1×10⁵ Ω·cm, further preferably lower than or equal to 1×10⁴ Ω·cm. Since the conductive layer 101b has conductivity, a property of electron or hole injection from the electrode 101 to the EL layer 100 can be improved and the drive voltage of the light-emitting element 150 can be reduced.

The hole-injection layer 111 preferably includes an organic acceptor material to improve a hole-injection property from the electrode 101 to the EL layer 100. The organic acceptor material is an organic material whose lowest unoccupied molecular orbital (also referred to as LUMO) level is low. The organic acceptor material can generate electrons and holes by charge separation when the organic acceptor material is used with a material having a highest occupied molecular orbital (also referred to as HOMO) at energy close to the LUMO level of the organic acceptor material. Thus, in the light-emitting element 150, charge separation occurs between the hole-injection layer 111 including an organic acceptor material and the hole-transport layer 112, so that electrons and holes are generated in the hole-injection layer 111 and the hole-transport layer 112, respectively. When voltage is applied between the electrode 101 and the electrode 102 so that the potential of the electrode 101 is higher than that of the electrode 102, the electrons generated owing to the charge separation are transported to the electrode 101 by the organic acceptor material, and the holes are transported to the light-emitting layer 130 by the material of the hole-transport layer 112. In that case, the hole-transport layer 112 preferably includes a hole-transport material. At the same time, the electrons injected from the electrode 102 are transported to the light-emitting layer 130 by the materials of the electron-injection layer 119 and the electron-transport layer 118. After that, when holes and electrons are recombined in the light-emitting layer 130, excitons are generated in the light-emitting layer 130, so that a light-emitting material in the light-emitting layer 130 emits light owing to excitation energy of the excitons.

Here, FIG. 2 shows an example of a correlation of energy levels of the electrode 101, the hole-injection layer 111, and the hole-transport layer 112 in the light-emitting element 150. In FIG. 2, 101a represents the metal in the conductive layer 101a, 101b represents the oxide in the conductive layer 101b, 111 represents the organic acceptor material in the hole-injection layer 111, 112 represents the hole-transport material in the hole-transport layer 112, Ef represents the Fermi level, Ec represents the energy level of the conduction band minimum, and Ev represents the energy level of the valence band maximum.

When the difference between the LUMO level of the organic acceptor material and the HOMO level of the hole-transport material of the hole-transport layer 112 is large, extraction of electrons from the hole-transport layer 112 by the hole-injection layer 111 becomes difficult. In other words, injection of holes from the hole-injection layer 111 to the hole-transport layer 112 becomes difficult. Therefore, the difference between the LUMO level of the organic acceptor material and the HOMO level of the hole-transport material of the hole-transport layer 112 is preferably small, specifically, preferably greater than or equal to 0 eV and less than or equal to 1.0 eV, more preferably greater than or equal to 0 eV and less than or equal to 0.5 eV, still more preferably greater than or equal to 0 eV and less than or equal to 0.3 eV. In that case, the difference between the LUMO level of the organic acceptor material and the HOMO level of the hole-transport material is preferably smaller than the difference between the LUMO level of the organic acceptor material and the LUMO level of the hole-transport material.

When the difference between the absolute value of the energy level of the conduction band minimum of the oxide of the conductive layer 101b and the absolute value of the LUMO level of the organic acceptor material of the hole-injection layer 111 is large in a region where the electrode 101 and the EL layer 100 are in contact with each other, electron injection from the hole-injection layer 111 to the conductive layer 101b is difficult. Therefore, the difference between the absolute value of the energy level of the conduction band minimum of the oxide of the conductive layer 10b and the absolute value of the LUMO level of the organic acceptor material of the hole-injection layer 111 is preferably small, specifically, preferably greater than or equal to 0 eV and less than or equal to 1.0 eV, more preferably greater than or equal to 0 eV and less than or equal to 0.5 eV, still more preferably greater than or equal to 0 eV and less than or equal to 0.3 eV. Alternatively, the difference between the absolute value of the Fermi level of the oxide of the conductive layer 101b and the absolute value of the LUMO level of the organic acceptor material of the hole-injection layer 111 is preferably small, specifically, preferably greater than or equal to 0 eV and less than or equal to 1.0 eV, more preferably greater than or equal to 0 eV and less than or equal to 0.5 eV, still more preferably greater than or equal to 0 eV and less than or equal to 0.3 eV. Note that when the oxide of the conductive layer 101b is in a degenerate state, the energy level of the conduction band minimum is substantially equal to the Fermi level.

Note that the LUMO level of the organic acceptor material of the hole-injection layer 111 is preferably higher than the energy level of the conduction band minimum or the Fermi level of the oxide of the conductive layer 101b so that electrons are efficiently injected from the hole-injection layer 111 to the electrode 101.

Furthermore, when the conductive layer 101b is formed over and in contact with the conductive layer 101a, oxygen vacancies are formed in the oxide of the conductive layer 101b and hydrogen is bonded to the oxygen vacancies, so that the resistance of the conductive layer 101b can be reduced. In that case, ohmic contact is made because the difference between the Fermi level of the conductive layer 101a and the Fermi level of the conductive layer 101b becomes small. Thus, electron is smoothly donated and accepted between the conductive layer 101a and the conductive layer 101b.

With a structure where the conductive layer 101a and the conductive layer 101b, which are included in the electrode 101, are in contact with each other, a difference in ionization tendency might arise between a material used for the conductive layer 101a and a material used for the conductive layer 101b (here, In).

The value of a standard electrode potential can be used as an index for an ionization tendency. For example, the standard electrode potential of Al is −1.68 V and that of In is −0.34 V; therefore, Al has a higher ionization tendency than In. In the case where a material containing Al is used for the conductive layer 101a and an oxide including In is used for the conductive layer 101b, the material containing Al and the oxide including In differ in ionization tendency; thus, electrons are donated and accepted between these materials, resulting in electrolytic corrosion. In addition, the bonding strength of Al with oxygen is higher than that of In with oxygen; therefore, oxygen might be donated and accepted between the material containing Al and the oxide including In, resulting in electrolytic corrosion, or an oxide of Al might be formed at an interface between the material containing Al and the oxide including In. Since the oxide of Al has low conductivity, the conductivity of the electrode 101 is reduced and thus the drive voltage of the light-emitting element 150 is increased. Furthermore, electrolytic corrosion might cause film separation because it changes stress of the electrode.

Therefore, in one embodiment of the present invention, the oxide of the conductive layer 101b contains In and an element whose bond energy with oxygen is higher than that of In. Alternatively, the oxide of the conductive layer 101b contains In and an element whose ionization tendency is higher than that of In. Further alternatively, the oxide of the conductive layer 101b contains In and an element whose standard electrode potential is lower than that of In. In other words, the oxide of the conductive layer 101b contains In and a stabilizer M (M represents one or more of Al, silicon (Si), titanium (Ti), gallium (Ga), yttrium (Y), zirconium (Zr), lanthanum (La), cerium (Ce), neodymium (Nd), and hafnium (Hf)). When the oxide contains In, the conductivity of the conductive layer 101b can be increased. In addition, the light transmittance of the conductive layer 101b can be increased. Moreover, the work function of the conductive layer 101b can be increased, so that the hole-injection property to the EL layer 100 or the electron-injection property from the EL layer 100 can be improved and the drive voltage of the light-emitting element 150 can be reduced.

With such a structure, the bonding strength of the stabilizer M with oxygen is increased in the conductive layer 101b; thus, donation and acceptance of oxygen between the conductive layer 101b and the conductive layer 101a can be prevented. Therefore, electrolytic corrosion of the electrode 101 can be prevented, resulting in lower drive voltage of the light-emitting element 150.

Here, the standard electrode potentials of In and elements which are examples that can be used as the stabilizer M are shown in Table 1. The calculated values of the bond energy between In and oxygen and between Ga, which is an example of the element that can be used as the stabilizer M, and oxygen are shown in Table 2.

TABLE 1

| | Standard electrode potential (V) |
|---|---|
| In | −0.34 |
| Al | −1.68 |
| Ti | −1.63 |
| Ga | −0.53 |
| Y | −2.37 |
| Zr | −1.55 |
| La | −2.37 |
| Ce | −2.34 |
| Nd | −2.32 |
| Hf | −1.70 |

TABLE 2

| | Bond energy (eV) |
|---|---|
| In—O | 1.83 |
| Ga—O | 2.39 |

Chemistry manual (the 4th edition of revision) basic volume (II) published by Maruzen Co., Ltd. is referred to for the standard electrode potentials in Table 1. As shown in Table 1, when an element whose standard electrode potential is lower than that of In is contained in the first oxide as the stabilizer M, the difference between the standard electrode potential of the conductive layer 101b and that of the conductive layer 101a containing Al is reduced; thus, redox reaction between the conductive layer 101b and the conductive layer 101a is less likely to occur. In other words, it is possible to prevent donation and acceptance of electrons or oxygen between the conductive layer 101a containing Al and the conductive layer 101b.

In the calculation of the bond energy between the metal elements and oxygen shown in Table 2, first principles calculation software VASP (the Vienna Ab initio Simulation Package) was used. FIGS. 3A and 3B illustrate crystal models used for the calculation. The effect of inner-shell electron was calculated by a projector augmented wave (PAW) method, and as a functional, generalized-gradient-approximation/Perdew-Burke-Emzerhof (GGA/PBE) was used. The calculation conditions are shown in Table 3.

TABLE 3

| | |
|---|---|
| Software | VASP |
| Calculation model | bixbyite-In₂O₃: 80 atoms |
| | β-Ga₂O₃: 80 atoms |
| Functional | GGA/PBE |
| Pseudo potential | PAW |
| Cut-off energy | 500 eV |
| K-point | 3 × 3 × 3 (bixbyite-In₂O₃) |
| | 3 × 5 × 3 (β-Ga₂O₃) |

In addition, the bond energy with oxygen (E_{binding} (M-O)) was calculated from Formula 1. Note that in Formula 1, M represents In or Ga and n represents the number of atoms depending on the model size, here n=16. Eₐₜₒₘ(M) and Eₐₜₒₘ(O) are total energy of M and O, respectively, and Eₜₒₜ(M₂ₙO₃ₙ) is total energy of an M₂O₃ crystal model. As in FIG. 3B, an In₂O₃ crystal includes only hexacoordinate In atoms and tetracoordinate O atoms, and the strength of the In—O bond can be regarded constant. In contrast, as in FIG. 3A, in a β-Ga₂O₃ crystal, energies of Ga—O bonds are not uniform because there are tricoordinate and tetracoordinate O atoms and tetracoordinate and hexacoordinate Ga atoms. However, their average value was used as the energy of the Ga—O bond to simplify the calculation.

$$\begin{matrix}[ Formula 1 ] & \\ {E}_{binding} ( M - O ) = \frac{2 n \times {E}_{atom} ( M ) + 3 n \times {E}_{atom} ( O ) - {E}_{tot} ( {M}_{2 n} {O}_{3 n} )}{( the number of bonds in the model )} & ( 1 )\end{matrix}$$

As a result of the calculation, as in Table 2, the energy of the Ga—O bond is higher than the energy of the In—O bond. Thus, Ga bonds with oxygen more strongly.

Note that in an oxide including a plurality of metal elements like an In—Ga—Zn oxide, oxygen is more likely to bond with two or three kinds of metal elements than with a single metal element. Therefore, bond energy between a metal element and oxygen (M-O) was calculated next with a crystal model having an atomic ratio of In to Ga and Zn of 1:1:1. The number of atoms in the model was 84, and the conditions shown in Table 3 were used for the calculation. The bond energy (E_{B,MO}) was calculated from Formula 2. In Formula 2, the bond energy (E_{B,M-O}) depends on a distance between M and O (d_{M-O}). In Formula 2, a_{0,M}, a_{1,M}, and a_{2,M} were calculated by fitting so that S in Formula 3 has a minimum value. Note that in Formula 4, IGZO:V_{O} represents a model of an In—Ga—Zn oxide in which oxygen vacancy (Vo) exists in the In—Ga—Zn oxide, and E(Vo) represents Vo generation energy in the model.

$$\begin{matrix}[ Formula 2 ] & \\ {E}_{B , M - O} ( {d}_{M - O} ) = {a}_{0 , M} + {a}_{1 , M} {d}_{M - O} + {a}_{2 , M} {d}_{M - O}^{2} & ( 2 ) \\ [ Formula 3 ] & \\ S = {\sum }_{i = {allV}_{O}} {( E ( {V}_{O} ) - {\sum }_{j = all\_coordinated \_Metal} ( {a}_{0 , j} + {a}_{1 , j} {d}_{j - O , i} + {a}_{2 , j} {d}_{j - O , i}^{2} ) )}^{2} & ( 3 ) \\ [ Formula 4 ] & \\ E ( {V}_{O} ) = {E}_{tot} ( IGZO \text{:} {V}_{O} ) + {E}_{atom} ( O ) - {E}_{tot} ( IGZO ) & ( 4 )\end{matrix}$$

The energy of the Ga—O bond between which the average distance was 0.195 nm was calculated to be 2.33 eV, and the energy of the In—O bond between which the average distance was 0.220 nm was calculated to be 1.80 eV. Therefore, also in an oxide including a plurality of metal elements like an In—Ga—Zn oxide, the energy of the Ga—O bond is higher than the energy of the In—O bond and thus Ga bonds with oxygen more strongly.

As described above, when an element whose standard electrode potential is lower than that of In, an element whose ionization tendency is higher than that of In, or an element whose bond energy with oxygen is higher than that of In is used as the stabilizer M for the conductive layer 101b, it is possible to inhibit donation and acceptance of electrons or oxygen between the conductive layer 101b containing In and the conductive layer 101a containing Al. In other words, when the conductive layer 101b is formed using an oxide containing In and the stabilizer M (M represents one or more of Al, Si, Ti, Ga, Y, Zr, La, Ce, Nd, and Hf), electrolytic corrosion of the electrode 101 can be prevented and accordingly the drive voltage of the light-emitting element 150 can be reduced.

Note that the standard electrode potential of Ag is 0.80 V; therefore, Ag has a lower ionization tendency than In. Thus, a material containing Ag is preferably used for the conductive layer 101a, in which case donation and acceptance of oxygen from the conductive layer 101b to the conductive layer 101a is less likely to occur. However, also in this case, the conductive layer 101b is preferably formed using an oxide containing In and the stabilizer M (M represents one or more of Al, Si, Ti, Ga, Y, Zr, La, Ce, Nd, and Hf) because the bonding strength with oxygen in the conductive layer 101b is further increased and thus the electrode 101 which is more stable can be formed.

The electrode 102 has a function of transmitting light. When the electrode 102 is formed using a material containing at least one of In, Ag, and magnesium (Mg), the light transmittance of the electrode 102 can be increased and the emission efficiency of the light-emitting element 150 can be increased.

In the case where the electrode 102 has functions of transmitting light and reflecting light, the emission efficiency of the light-emitting element 150 can be increased by a microcavity effect. For this reason, it is preferable to use the material containing at least one of In, Ag, and Mg for the electrode 102.

The electrode 101 may have functions of reflecting light and transmitting light. In such a case, the conductive layer 101a of the electrode 101 is preferably thin enough to transmit light. In the case where the electrode 101 has functions of reflecting light and transmitting light, the electrode 102 preferably has a function of reflecting light and particularly preferably includes Ag having high reflectance.

When a color filter is provided over the electrode through which light is extracted, the color purity of the light-emitting element 150 can be improved. Therefore, the color purity of a display device including the light-emitting element 150 can be improved.

The light-emitting layer 130 may have a stacked-layer structure of a plurality of layers. For example, when light-emitting materials having functions of emitting light of different colors are used for a first light-emitting layer and a second light-emitting layer, light of a plurality of emission colors can be obtained from the light-emitting element 150. In addition, it is preferable to select light-emitting materials so that white light can be obtained by combining light emission from the light-emitting layer 130.

The light-emitting layer 130 may have a structure in which three or more layers are stacked or may include a layer having no light-emitting material.

### <Components of Light-Emitting Element>

Components of the light-emitting elements illustrated in FIG. 1 are described in detail below.

### <<Pair of Electrodes>>

The electrode 101 functions as an anode or a cathode of the light-emitting element.

The conductive layer 101a of the electrode 101 is preferably formed using a conductive material having a function of reflecting light. Examples of the conductive material include Al, an alloy containing Al, and the like. Examples of the alloy containing Al include an alloy containing Al and L (L represents one or more of Ti, Nd, nickel (Ni), and La), and the like. Aluminum has low resistance and high light reflectance. Aluminum is included in earth's crust in large amount and is inexpensive; therefore, it is possible to reduce cost for manufacturing a light-emitting element with aluminum. Alternatively, Ag, an alloy containing Ag, and the like may be used, and examples of the alloy containing Ag include an alloy containing Ag and N (N represents one or more of Y, Nd, Mg, Al, Ti, Ga, Zn, In, tungsten (W), manganese (Mn), Sn, iron (Fe), Ni, copper (Cu), palladium (Pd), iridium (Ir), and gold (Au)), and the like. Examples of the alloy containing silver include an alloy containing silver, palladium, and copper, an alloy containing silver and copper, an alloy containing silver and magnesium, an alloy containing silver and nickel, an alloy containing silver and gold, and the like. Note that in the case where light is extracted through the electrode 101, it is preferable that the conductive layer 101a be formed of a thin film having a thickness that allows transmission of light (preferably, approximately greater than or equal to 5 nm and less than or equal to 30 nm) using a metal exemplified as the above conductive material and have functions of reflecting light and transmitting light.

Furthermore, the conductive layer 101b of the electrode 101 is preferably formed using an oxide including In and the stabilizer M (M represents one or more of Al, Si, Ti, Ga, Y, Zr, Sn, La, Ce, Nd, and Hf). With such a structure, it is possible to suppress donation and acceptance of electrons or oxygen between the conductive layer 101b and the conductive layer 101a. Therefore, electrolytic corrosion of the electrode 101 can be prevented, resulting in lower drive voltage of the light-emitting element.

As another example of the stabilizer M, one or a plurality of kinds of lanthanoid such as praseodymium (Pr), samarium (Sm), europium (Eu), gadolinium (Gd), terbium (Tb), dysprosium (Dy), holmium (Ho), erbium (Er), thulium (Tm), ytterbium (Yb), or lutetium (Lu) may be contained.

The conductive layer 101b may include a metal element other than In and the stabilizer M. A material containing zinc (Zn) or zinc oxide is particularly preferable because a film with a uniform thickness can be formed. In other words, an oxide including In, the stabilizer M, and Zn is preferably used for the conductive layer 101b.

As an oxide included in the conductive layer 101b, any of the following can be used, for example: an In—Ga—Zn-based oxide, an In—Al—Zn-based oxide, an In—Si—Zn-based oxide, an In—Ti—Zn-based oxide, an In—Ti—Y-based oxide, an In—Zr—Zn-based oxide, an In—Sn—Zn-based oxide, an In—La—Zn-based oxide, an In—Ce—Zn-based oxide, an In—Nd—Zn-based oxide, an In—Hf—Zn-based oxide, an In—Pr—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

In the case where the conductive layer 101b is an In—Ga—Zn-based oxide, as a sputtering target used for forming the In—Ga—Zn oxide, it is preferable to use an In—Ga—Zn-based oxide having an atomic ratio of In:Ga:Zn=1:1:1, In:Ga:Zn=1:3:2, In:Ga:Zn=1:3:3, In:Ga:Zn=1:3:4, In:Ga:Zn=1:3:5, In:Ga:Zn=1:3:6, In:Ga:Zn=1:3:7, In:Ga:Zn=1:3:8, In:Ga:Zn=1:3:9, In:Ga:Zn=1:3:10, In:Ga:Zn=1:4:4, In:Ga:Zn=1:4:5, In:Ga:Zn=1:5:5, In:Ga:Zn=1:6:4, In:Ga:Zn=1:6:5, In:Ga:Zn=1:6:6, In:Ga:Zn=1:6:7, In:Ga:Zn=1:6:8, In:Ga:Zn=1:6:9, In:Ga:Zn=1:6:10, In:Ga:Zn=1:9:4, In:Ga:Zn=1:1:4, In:Ga:Zn=5:5:6, In:Ga:Zn=3:1:2, In:Ga:Zn=2:1:3, or In:Ga:Zn=4:2:4.1, or an oxide whose composition is in the neighborhood of the above composition. Note that the atomic ratio of metal elements in the conductive layer 101b formed using the above sputtering target varies from the above atomic ratio of metal elements of the sputtering target within a range of ±20% as an error.

The proportion of the stabilizer M is preferably high because the stabilizer M is a metal element which has a high bonding strength to oxygen. In the case where the conductive layer 101b includes an In-M-Zn oxide, the proportions of In and M, not taking Zn and oxygen into consideration, are preferably lower than 75 atomic % and higher than 25 atomic %, respectively, more preferably lower than 66 atomic % and higher than 34 atomic %, respectively. With such a structure, it is possible to suppress donation and acceptance of electrons or oxygen between the conductive layer 101b and the conductive layer 101a.

In the case where the conductive layer 101b includes an In-M-Zn oxide, as for the atomic ratio of metal elements in a sputtering target used for forming the In-M-Zn oxide, it is preferable that the content of M is greater than or equal to that of In. In that case, the content of M is preferably greater than or equal to 1 time and smaller than 5 times that of In, more preferably greater than or equal to 1 time and smaller than or equal to 3 times that of In because the conductivity is lowered when the content of M is greater than or equal to 5 times that of In. Alternatively, when the sputtering target has the atomic ratio of metal elements of In:M:Zn=x:y:z, it is preferable that x≦y be satisfied and z/y be greater than or equal to ⅓ and less than or equal to 6, more preferably greater than or equal to 1 and less than or equal to 6. Typical examples of the atomic ratio of the metal elements of such a sputtering target include In:M:Zn=1:1:1, In:M:Zn=1:1:1.2, In:M:Zn=1:3:2, In:M:Zn=1:3:4, In:M:Zn=1:3:6, and In:M:Zn=1:3:8.

In order to improve the conductivity of the conductive layer 101b, as for the atomic ratio of metal elements in a sputtering target used for forming the In-M-Zn oxide, the content of In may be greater than or equal to that of M and that of Zn may be greater than or equal to that of M. Alternatively, when the sputtering target has the atomic ratio of metal elements of In:M:Zn=x:y:z, it is preferable that x/y be greater than or equal to ⅓ and less than or equal to 6, more preferably greater than or equal to 1 and less than or equal to 6, and z/y be greater than or equal to ⅓ and less than or equal to 6, more preferably greater than or equal to 1 and less than or equal to 6. Typical examples of the atomic ratio of the metal elements of such a sputtering target include In:M:Zn=1:1:1, In:M:Zn=1:1:1.2, In:M:Zn=3:1:2, and In:M:Zn=4:2:4.1. This is because in an oxide containing In, the stabilizer M, and Zn, the s orbital of heavy metal mainly contributes to carrier transfer, and a higher content of In in the oxide enlarges a region where the s orbitals of In atoms overlap; therefore, an oxide with a high content of In has higher conductivity than an oxide with a low content of In.

In an oxide semiconductor or the like, the difference between the energy level of the conduction band minimum and the energy level of the valence band maximum refers to a bandgap, and the difference between the vacuum level and the energy level of the conduction band minimum refers to electron affinity. The energy gap can be measured using a spectroscopic ellipsometer (UT-300 manufactured by HORIBA JOBIN YVON S.A.S.), for example. The difference between the vacuum level and the energy level of the valence band maximum can be measured using an ultraviolet photoelectron spectroscopy (UPS) device (VersaProbe manufactured by ULVAC-PHI, Inc.), for example. The electron affinity can be calculated by subtracting a bandgap from the difference between the vacuum level and the energy level of the valence band maximum.

An In—Ga—Zn oxide which is formed using a target having an atomic ratio of In:Ga:Zn=1:1:1 has an energy gap of approximately 3.2 eV and an electron affinity of approximately 4.7 eV. An In—Ga—Zn oxide which is formed using a target having an atomic ratio of In:Ga:Zn=1:3:2 has an energy gap of approximately 3.5 eV and an electron affinity of approximately 4.5 eV. An In—Ga—Zn oxide which is formed using a target having an atomic ratio of In:Ga:Zn=1:3:4 has an energy gap of approximately 3.4 eV and an electron affinity of approximately 4.5 eV. An In—Ga—Zn oxide which is formed using a target having an atomic ratio of In:Ga:Zn=1:3:6 has an energy gap of approximately 3.3 eV and an electron affinity of approximately 4.5 eV. An In—Ga—Zn oxide which is formed using a target having an atomic ratio of In:Ga:Zn=1:6:2 has an energy gap of approximately 3.9 eV and an electron affinity of approximately 4.3 eV. An In—Ga—Zn oxide which is formed using a target having an atomic ratio of In:Ga:Zn=1:6:8 has an energy gap of approximately 3.5 eV and an electron affinity of approximately 4.4 eV. An In—Ga—Zn oxide which is formed using a target having an atomic ratio of In:Ga:Zn=1:6:10 has an energy gap of approximately 3.5 eV and an electron affinity of approximately 4.5 eV. An In—Ga—Zn oxide which is formed using a target having an atomic ratio of In:Ga:Zn=3:1:2 has an energy gap of approximately 2.8 eV and an electron affinity of approximately 5.0 eV. An In—Ga—Zn oxide which is formed using a target having an atomic ratio of In:Ga:Zn=3:1:4 has an energy gap of approximately 2.8 eV and an electron affinity of approximately 4.6 eV. An In—Ga—Zn oxide which is formed using a target having an atomic ratio of In:Ga:Zn=4:2:4.1 has an energy gap of approximately 3.0 eV and an electron affinity of approximately 4.4 eV. As described above, when the oxide in which the amount of the stabilizer M is larger than or equal to that of In in an atomic ratio, the energy gap of the oxide may increase and the electron affinity of the oxide may decrease. In other words, by changing the atomic ratio of In to the stabilizer M in the oxide, the energy level of the conduction band minimum of the oxide can be changed.

The conductive layer 101b can be formed by a sputtering method, a molecular beam epitaxy (MBE) method, a chemical vapor deposition (CVD) method, a pulsed laser deposition (PLD) method, an atomic layer deposition (ALD) method, or the like as appropriate.

The conductive layer 101b of the electrode 101 can have a function of adjusting the optical path length so that light having a desired wavelength among light emitted from each light-emitting layer resonates and can be intensified.

A transparent conductive layer may be formed over the conductive layer 101b. The transparent conductive layer can be formed using, for example, indium tin oxide (hereinafter, referred to as ITO), indium tin oxide containing silicon or silicon oxide (ITSO), indium oxide-zinc oxide (indium zinc oxide), indium oxide containing tungsten oxide and zinc oxide, or the like. In particular, in the case where the electrode 101 is used as an anode, the transparent conductive layer is preferably formed using a material having a high work function (higher than or equal to 4.0 eV). The transparent conductive layer can be formed by a sputtering method, an evaporation method, a printing method, a coating method, or the like.

In this specification and the like, a transparent conductive layer transmits visible light and has conductivity. Examples of the transparent conductive layer include, in addition to the above-described oxide conductor layer typified by an ITO, an oxide semiconductor layer and an organic conductive layer containing an organic substance. Examples of the organic conductive layer containing an organic substance include a layer containing a composite material in which an organic compound and an electron donor (donor) are mixed, a layer containing a composite material in which an organic compound and an electron acceptor (acceptor) are mixed, and the like. The resistivity of the transparent conductive layer is preferably lower than or equal to 1×10⁵ Ω·cm, further preferably lower than or equal to 1×10⁴ Ω·cm.

Note that in the case where a field-effect transistor (FET) is formed in addition to the light-emitting element, an oxide semiconductor layer used for a channel region of the transistor and the conductive layer 101b of the electrode 101 preferably include the same elements. In other words, the oxide semiconductor layer used for the channel region of the transistor preferably includes In and the stabilizer M (M represents one or more of Al, Si, Ti, Ga, Y, Zr, La, Ce, Nd, and Hf). In addition, it is particularly preferable to use the same materials for the oxide semiconductor layer and the conductive layer 101b. The use of common materials for the oxide semiconductor layer and the conductive layer 101b does not increase the kind of deposition materials; thus, the manufacturing cost can be reduced. In such a case, different film formation processes are used for the oxide semiconductor layer and the conductive layer 101b. In other words, pressure, film formation gas (e.g., oxygen, argon, or a mixed gas including oxygen), film formation energy, a temperature at film formation, a distance between a target and a substrate in a film formation chamber at film formation, a temperature or surface treatment after the film formation, or the like can be changed between the oxide semiconductor layer and the conductive layer 101b so that the oxide semiconductor layer and the conductive layer 101b have different properties, so that the oxide semiconductor layer and the conductive layer 101b each have a different function. Note that in this specification and the like, a “semiconductor” or “semiconductor layer” includes characteristics of a “conductor” or “conductive layer” in some cases when the conductivity is sufficiently high, for example. Furthermore, it is difficult to strictly distinguish a “semiconductor” and a “conductor” or a “semiconductor layer” and a “conductive layer” from each other in some cases because a border between them is not clear. Accordingly, a “semiconductor” in this specification and the like can be called a “conductor” and a “semiconductor layer” in this specification and the like can be called a “conductor layer” in some cases.

An oxide semiconductor is a semiconductor material whose resistance can be controlled by oxygen vacancy in the film of the semiconductor material and/or the concentration of impurities such as hydrogen or water in the film of the semiconductor material. Thus, treatment to be performed on the oxide semiconductor layer and the conductive layer 101b is selected from the following to control the resistivity of each of the oxide semiconductor layer and the conductive layer 101b formed with the same materials: treatment for increasing oxygen vacancy and/or impurity concentration and treatment for reducing oxygen vacancy and/or impurity concentration.

Specifically, plasma treatment is performed on the conductive layer 101b functioning as part of the pixel electrode to increase oxygen vacancies and/or impurities such as hydrogen or water in the conductive layer 101b, so that a donor level is formed in the vicinity of the conduction band, and thus, an oxide layer with a higher carrier density and a lower resistance can be obtained. Furthermore, an insulating film or conductive layer containing hydrogen is formed in contact with the conductive layer 101b to diffuse hydrogen from the insulating film or the conductive layer containing hydrogen to the conductive layer 101b, so that the conductive layer 101b can be an oxide layer with a higher carrier density and a lower resistance.

In contrast, an insulating film is preferably provided over the oxide semiconductor layer used for the channel region of the transistor to prevent the oxide semiconductor layer from being subjected to the plasma treatment. Since the insulating film is provided, the oxide semiconductor layer is not in contact with the insulating film containing hydrogen, which is in contact with the conductive layer 101b. An insulating film capable of releasing oxygen is provided over the oxide semiconductor layer, whereby oxygen can be supplied to the oxide semiconductor layer. The oxide semiconductor layer to which oxygen is supplied is a high-resistance oxide semiconductor in which oxygen vacancy in the film or at the interface is filled. Note that as the insulating film capable of releasing oxygen, a silicon oxide film or a silicon oxynitride film can be used, for example.

As the plasma treatment to be performed on the conductive layer 101b, plasma treatment using a gas containing one of a rare gas (He, Ne, Ar, Kr, or Xe), hydrogen, and nitrogen is typical. Specifically, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, plasma treatment in a nitrogen atmosphere, or the like can be employed.

By the plasma treatment, an oxygen vacancy is formed in a lattice from which oxygen is released (or in a portion from which oxygen is released) in the conductive layer 101b. This oxygen vacancy can cause carrier generation. When the oxygen vacancy is combined with hydrogen supplied from the vicinity of the conductive layer 101b, specifically, from an insulating film or a conductive layer that is in contact with the lower surface or the upper surface of the conductive layer 101b, an electron serving as a carrier can be generated. Accordingly, the conductive layer 101b whose oxygen vacancy is increased by the plasma treatment has higher carrier density than the oxide semiconductor layer.

The layer containing hydrogen, that is, a layer capable of releasing hydrogen is formed in contact with the conductive layer 101b, whereby hydrogen can be supplied to the conductive layer 101b. The layer capable of releasing hydrogen preferably has a concentration of hydrogen of 1×10²² atoms/cm³ or higher or 5×10²² atoms/cm³ or higher. Such a layer is formed in contact with the conductive layer 101b, whereby hydrogen can be effectively contained in the conductive layer 101b. In this manner, the above plasma treatment is performed and the structure of the layer in contact with the conductive layer 101b is changed, whereby the resistance of the conductive layer 101b can be appropriately adjusted.

The oxide semiconductor layer in which oxygen vacancy is filled with oxygen and the concentration of hydrogen is reduced can be referred to as a highly purified intrinsic or substantially highly purified intrinsic oxide semiconductor layer. The term “substantially intrinsic” refers to the state where an oxide semiconductor layer has a carrier density lower than 8×10¹¹/cm³, preferably lower than 1×10¹¹/cm³ and further preferably lower than 1×10¹⁰/cm³, and higher than or equal to 1×10⁻⁹/cm³. A highly purified intrinsic or substantially highly purified intrinsic oxide semiconductor has few carrier generation sources, and thus has a low carrier density. The highly purified intrinsic or substantially highly purified intrinsic oxide semiconductor layer has a low density of defect states and accordingly can have a low density of trap states.

Furthermore, the highly purified intrinsic or substantially highly purified intrinsic oxide semiconductor layer has an extremely low off-state current; even when an element has a channel width W of 1×10⁶ μm and a channel length L of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V. Accordingly, the transistor in which the channel region is formed in the oxide semiconductor layer can have a small variation in electrical characteristics and high reliability.

Hydrogen contained in the conductive layer 101b reacts with oxygen bonded to a metal atom to be water, and also causes oxygen vacancy in a lattice from which oxygen is released (or a portion from which oxygen is released). Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, the conductive layer 101b containing hydrogen is an oxide layer having a higher carrier density than the oxide semiconductor layer.

In other words, the conductive layer 101b functioning as part of the electrode 101 is a low-resistance oxide layer that has a high concentration of hydrogen and/or a large amount of oxygen vacancy as compared with the oxide semiconductor layer including the channel region of the transistor.

Hydrogen in the oxide semiconductor layer of the transistor in which a channel region is formed is preferably reduced as much as possible. Specifically, in the oxide semiconductor layer, the concentration of hydrogen which is measured by secondary ion mass spectrometry (SIMS) is lower than or equal to 5×10¹⁹ atoms/cm³, preferably lower than or equal to 1×10¹⁹ atoms/cm³, further preferably lower than 5×10¹⁸ atoms/cm³, further preferably lower than or equal to 1×10¹⁸ atoms/cm³, further preferably lower than or equal to 5×10¹⁷ atoms/cm³, and further preferably lower than or equal to 1×10¹⁶ atoms/cm³.

It is preferable to perform heat treatment after the oxide semiconductor layer used for the channel region of the transistor is formed. The heat treatment is preferably performed at a temperature higher than or equal to 250° C. and lower than or equal to 650° C., preferably higher than or equal to 300° C. and lower than or equal to 400° C., and further preferably higher than or equal to 320° C. and lower than or equal to 370° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen. The heat treatment here allows impurities such as hydrogen and water to be removed from the oxide semiconductor layer. Note that the heat treatment may be performed before the oxide semiconductor layer is processed into an island shape.

Note that stable electrical characteristics can be effectively imparted to a transistor in which an oxide semiconductor serves as a channel by reducing the concentration of impurities in the oxide semiconductor to make the oxide semiconductor intrinsic or substantially intrinsic.

The thickness of the oxide semiconductor layer is greater than or equal to 3 nm and less than or equal to 200 nm, preferably greater than or equal to 3 nm and less than or equal to 100 nm, and further preferably greater than or equal to 3 nm and less than or equal to 50 nm.

The oxide semiconductor layer in which the amount of the stabilizer M is larger than or equal to the amount of In in an atomic ratio may have any of the following effects: (1) the energy gap of the oxide semiconductor layer is widened; (2) the electron affinity of the oxide semiconductor layer decreases; (3) an impurity from the outside is blocked; and (4) an insulating property increases. Furthermore, oxygen vacancy is less likely to be generated in the oxide semiconductor layer containing the amount of the stabilizer M larger than or equal to the amount of In in an atomic ratio because the stabilizer M is a metal element which is strongly bonded to oxygen.

Note that, without limitation to those described above, a material with an appropriate composition may be used for the oxide semiconductor layer depending on required semiconductor characteristics and electrical characteristics (e.g., field-effect mobility and threshold voltage) of a transistor. Furthermore, in order to obtain required semiconductor characteristics of a transistor, it is preferable that the carrier density, the impurity concentration, the defect density, the atomic ratio of a metal element to oxygen, the interatomic distance, the density, and the like of the oxide semiconductor layer be set to be appropriate.

The electrode 102 functions as an anode or a cathode of each light-emitting element. Note that in the case where the electrode 101 has a function of reflecting light, the electrode 102 is preferably formed using a conductive material having a function of transmitting light. As the conductive material, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used. The electrode 102 may be formed using a conductive material having functions of transmitting light and reflecting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. In the case where the electrode 101 has a function of transmitting light, the electrode 102 is preferably formed using a conductive material having a function of reflecting light.

The electrode 102 can be formed using one or more kinds of conductive metals and alloys, conductive compounds, and the like. For example, ITO, ITSO, indium oxide-zinc oxide (indium zinc oxide), indium oxide-tin oxide containing titanium, indium titanium oxide, indium oxide containing tungsten oxide and zinc oxide, or the like can be used. A metal thin film having a thickness that allows transmission of light (preferably, approximately greater than or equal to 5 nm and less than or equal to 30 nm) can also be used. As the metal, for example, Ag, an alloy of Ag and Al, an alloy of Ag and Mg, an alloy of Ag and Au, an alloy of Ag and Yb, or the like can be used. Particularly when the electrode 102 functions as a cathode, a material containing at least one metal element selected from In, Ag, and Mg is preferably used. In addition, it is preferable to use a material having a low work function (3.8 eV or less). The examples include an element belonging to Group 1 or 2 of the periodic table (e.g., an alkali metal such as lithium or cesium, an alkaline earth metal such as calcium or strontium, or magnesium), an alloy containing any of these elements (e.g., Ag—Mg or Al—Li), a rare earth metal such as europium or ytterbium, an alloy containing any of these rare earth metals, an alloy containing aluminum and silver, and the like. The electrode 102 can be formed by a sputtering method, an evaporation method, a printing method, a coating method, or the like.

### <<Hole-Injection Layer>>

The hole-injection layer 111 injects holes from the anode to the EL layer 100. The hole-injection layer 111 preferably includes an organic acceptor material.

Although there is no particular limitation on the organic acceptor material, an organic material having an electron-withdrawing property is preferably used. For example, compounds with an electron-withdrawing group, such as a halogen group or a cyano group are preferably used. Specifically, 7,7,8,8-tetracyano-2,3,5,6-tetrafluoroquinodinethane (abbreviation: F₄-TCNQ), 3,6-difluoro-2,5,7,7,8,8-hexacyanoquinodimethane, chloranil, or the like can be used. A compound having a carbonyl group, e.g., a compound having a perylenetetracarbonyl skeleton can be used. A compound having a π-electron deficient heteroaromatic skeleton is preferably used, and in particular, a compound having a nitrogen-containing heteroaromatic skeleton is preferably used, and a compound having a heteroaromatic skeleton including a plurality of nitrogen atoms is more preferably used. Specifically, for example, a pyrazine skeleton and an azatriphenylene skeleton are preferable, tetraazatriphenylene having four nitrogen atoms or the like is more preferable, and a hexaazatriphenylene having six nitrogen atoms are more preferable. Specifically, for example, pyrazino[2,3-f][1,10]phenanthroline-2,3-dicarbonitrile (abbreviation: PPDN), 2,3,6,7,10,11-hexacyano-1,4,5,8,9,12-hexaazatriphenylene (abbreviation: HAT-CN), and the like are given. HAT-CN is particularly preferable because it has a high acceptor property and exhibits stable film quality. A material is selected from these organic acceptor materials so that the correlation in energy level between the oxide in the conductive layer 101b and the hole-transport material of the hole-transport layer 112 satisfies one embodiment of the present invention. Note that these organic acceptor materials are suitable for mass production because they can be formed at relatively low temperatures.

The difference in energy level between the LUMO level of the organic acceptor material of the hole-injection layer 111 and the energy level of the conduction band minimum of the oxide of the anode is preferably small, specifically, preferably greater than or equal to 0 eV and less than or equal to 1.0 eV, more preferably greater than or equal to 0 eV and less than or equal to 0.5 eV, still more preferably greater than or equal to 0 eV and less than or equal to 0.3 eV. In the case where the hole-injection layer 111 includes a region in contact with the electrode 101, more strictly, the conductive layer 101b and an In—Ga—Zn oxide is used for the conductive layer 101b, the difference between the energy level of the conduction band minimum and the vacuum level of the In—Ga—Zn oxide, i.e., electron affinity, is from 4.3 eV to 4.7 eV as described above. Therefore, the LUMO level of the organic acceptor material of the hole-injection layer 111 is preferably greater than or equal to −5.7 eV and less than or equal to −3.3 eV, more preferably greater than or equal to −5.2 eV and less than or equal to −3.8 eV, still more preferably greater than or equal to −5.0 eV and less than or equal to −4.0 eV. For example, HAT-CN has a LUMO level of −4.41 eV and thus is an organic acceptor material suitable for one embodiment of the present invention.

Note that the LUMO levels and the HOMO levels of the compounds can be derived from the electrochemical characteristics (the reduction potentials and the oxidation potentials) of the compounds that are measured by cyclic voltammetry (CV), for example.

The hole-injection layer 111 may include another acceptor material. The acceptor material and the organic acceptor material are mixed or stacked to be used for the hole-injection layer 111. As the acceptor material, a transition metal oxide can be given. In addition, oxides of metals belonging to Groups 4 to 8 in the periodic table can be also given. Specifically, vanadium oxide, niobium oxide, tantalum oxide, chromium oxide, molybdenum oxide, tungsten oxide, manganese oxide, rhenium oxide, and ruthenium oxide are preferable since their electron-accepting property is high. Among these, molybdenum oxide is particularly preferable because it is stable in the air, has a low hygroscopic property, and is easily handled. Note that the hole-injection layer 111 may be formed of the acceptor material either alone or in combination with another material. For example, a composite material including an acceptor material and a hole-transport material can be used. By including an acceptor material and a hole-transport material, an electron is extracted from the hole-transport material by the acceptor material and a hole is generated in the hole-transport material and is injected to the light-emitting layer 130 through the hole-transport layer 112.

Examples of the hole-transport material used for the hole-injection layer 111 include aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris(N,N′-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(spiro-9,9′-bifluoren-2-yl)-N-phenylamino]biphenyl (abbreviation: BSPB), 4,4′-bis[N-(4-diphenylaminophenyl)-N-phenylamino]biphenyl (abbreviation: DPAB), and N,N′-bis{4-[bis(3-methylphenyl)amino]phenyl}-N,N′-diphenyl-[1,1′-biphenyl]-4,4′-diamine (abbreviation: DNTPD); 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like. Alternatively, any of the following carbazole derivatives can be used: 4,4′-di(N-carbazolyl)biphenyl (abbreviation: CBP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). The substances described here are mainly substances having a hole mobility of 1×10⁻⁶ cm²Ns or higher. However, other substances may be used as long as their hole-transport properties are higher than their electron-transport properties.

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can also be used.

Alternatively, phthalocyanine-based compound such as phthalocyanine (abbreviation: H₂Pc) or copper phthalocyanine (abbreviation: CuPc), or a high molecule such as poly(3,4-ethylenedioxythiophene)/poly(styrenesulfonic acid) (abbreviation: PEDOT/PSS), or the like can be used.

### <<Hole-Transport Layer>>

The hole-transport layer 112 is a layer containing a hole-transport material and can be formed using any of the materials given as examples of the material of the hole-injection layer 111. The hole-transport layer 112 has a function of transporting holes injected from the hole-injection layer 111 to the light-emitting layer 130.

In that case, a hole-transport material whose HOMO level is between the LUMO level of the organic acceptor material of the hole-injection layer 111 and the HOMO level of the material of the light-emitting layer 130 is preferably used for the hole-transport layer 112. The hole-transport layer 112 is not limited to a single layer, and may include stacked two or more layers. In this case, hole-transport materials are preferably stacked so that their HOMO levels are decreased in this order from the hole-injection layer 111 side to the light-emitting layer 130 side. In the case where the hole-transport layer 112 includes stacked two or more layers, in order to transport holes smoothly, the difference in the HOMO level between hole-transport materials is preferably greater than or equal to 0 eV and less than or equal to 0.5 eV, more preferably greater than or equal to 0 eV and less than or equal to 0.3 eV, still more preferably greater than or equal to 0 eV and less than or equal to 0.2 eV.

Examples of the hole-transport material include compounds having aromatic amine skeletons such as 4,4′-bis[N-(1-naphthyl)-N-phenylamino]biphenyl (abbreviation: NPB), N,N′-bis(3-methylphenyl)-N,N′-diphenyl-[1, 1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylanine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties to contribute to a reduction in drive voltage. Hole-transport materials can be selected from a variety of substances as well as from the hole-transport materials given above.

Furthermore, examples of the substance having a high hole-transport property include compounds having aromatic amine skeletons, such as 3-[4-(1-naphthyl)-phenyl]-9-phenyl-9H-carbazole (abbreviation: PCPN), 3-[4-(9-phenanthryl)-phenyl]-9-phenyl-9H-carbazole (abbreviation: PCPPn), 4-phenyl-4′-(9-phenyl-9H-carbazol-3-yl)triphenylamine (abbreviation: PCBA1BP), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), 3,3′-bis(9-phenyl-9H-carbazole) (abbreviation: PCCP), N-[4-(9H-carbazol-9-yl)phenyl]-N-(4-phenyl)phenylaniline (abbreviation: YGA1BP), 1,3,5-tri(dibenzothiophen-4-yl)-benzene (abbreviation: DBT3P-II), 4,4′,4″-(benzene-1,3,5-triyl)tri(dibenzofuran) (abbreviation: DBF3P-II), 4-phenyl-4′-(9-phenylfluoren-9-yl)triphenylamine (abbreviation: BPAFLP), 4-[3-(triphenylen-2-yl)phenyl]dibenzothiophene (abbreviation: mnDBTPTp-II), 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamnine (abbreviation: TCTA), 4,4′,4″-tris(N,N′-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluoren-2-yl)-N-phenylamino]biphenyl (abbreviation: BSPB); 3-[N-(9-phenylcarbazol-3-yl)-N-phenylamino]-9-phenylcarbazole (abbreviation: PCzPCA1; 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like. Other examples include carbazole compounds such as 4,4′-di(N-carbazolyl)biphenyl (abbreviation: CBP) and 1,3,5-tris[4-(N-carbazolyl)phenyl]benzene (abbreviation: TCPB); amine compounds; dibenzothiophene compounds; dibenzofuran compounds; fluorene compounds; triphenylene compounds; and phenanthrene compounds. The substances given here are mainly substances having a hole mobility of 1×10⁻⁶ cm²/Vs or more. Note that any other material may be used as long as it has a property of transporting more holes than electrons.

Note that any of these compounds that can be used for the hole-transport layer can also be used for the hole-injection layer.

### <<Light-Emitting Layer>>

The light-emitting layer 130 contains a light-emitting material having a function of emitting at least one of violet light, blue light, blue green light, green light, yellow green light, yellow light, orange light, and red light. In addition, the light-emitting layer 130 preferably contains an electron-transport material and/or a hole-transport material as a host material in addition to the light-emitting material.

As the light-emitting material, any of light-emitting substances that convert singlet excitation energy into luminescence and light-emitting substances that convert triplet excitation energy into luminescence can be used. Examples of the light-emitting substance are given below.

Examples of the light-emitting substance capable of converting singlet excitation energy into luminescence include substances that emit fluorescence (fluorescent compound). Although there is no particular limitation on the fluorescent compound, an anthracene derivative, a tetracene derivative, a chrysene derivative, a phenanthrene derivative, a pyrene derivative, a perylene derivative, a stilbene derivative, an acridone derivative, a coumarin derivative, a phenoxazine derivative, a phenothiazine derivative, or the like is preferably used, and for example, any of the following substances can be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9-phenyl-9H-fluoren-9-yl)phenyl]-N,N′-bis(4-tert-butylphenyl)pyrene-1,6-diamine (abbreviation: 1,6tBu-FLPAPrn), N,N′-diphenyl-N,N′-bis[4-(9-phenyl-9H-fluoren-9-yl)phenyl]-3,8-dicyclohexylpyrene-1, 6-diamine (abbreviation: ch-1,6FLPAPm), N,N′-(pyrene-1,6-diyl)bis[(6,N-diphenylbenzo[b]naphtho[1,2-d]furan)-8-amine] (abbreviation: 1,6BnfAPrn-03), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9, 10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 6, coumarin 545T, N,N′-diphenylquinacridone (abbreviation: DPQd), rubrene, 2,8-di-tert-butyl-5,11-bis(4-tert-butylphenyl)-6,12-diphenyltetracene (abbreviation: TBRb), Nile red, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[i]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[i]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and 5,10,15,20-tetraphenylbisbenzo[5,6]indeno[1,2,3-cd:1′,2′,3′-lm]perylene.

As an example of the light-emitting substance capable of converting triplet excitation energy into luminescence, a substance which emits phosphorescence (a phosphorescent compound) can be given. As the phosphorescent compound, an iridium-, rhodium-, or platinum-based organometallic complex or metal complex can be used. Furthermore, a platinum complex having a porphyrin ligand, an organoiridium complex, and the like can be given; specifically, an organoiridium complex such as an iridium-based ortho-metalated complex is preferable. As an ortho-metalated ligand, a 4H-triazole ligand, a 1H-triazole ligand, an imidazole ligand, a pyridine ligand, a pyrimidine ligand, a pyrazine ligand, an isoquinoline ligand, or the like can be given. In this case, the phosphorescent compound has an absorption band based on triplet MLCT (metal to ligand charge transfer) transition.

Examples of the substance that has an emission peak in the blue or green wavelength range include organometallic iridium complexes having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: Ir(mpptz-dmp)₃), tris(5-methyl-3,4-diphenyl-4H-1,2,4-triazolato)iridium(III) (abbreviation: Ir(Mptz)₃), tris[4-(3-biphenyl)-5-isopropyl-3-phenyl-4H-1,2,4-triazolato]iridium(III) (abbreviation: Ir(iPrptz-3b)₃), and tris[3-(5-biphenyl)-5-isopropyl-4-phenyl-4H-1,2,4-triazolato]iridium(III) (abbreviation: Ir(iPr5btz)₃); organometallic iridium complexes having a 1H-triazole skeleton, such as tris[3-methyl-1-(2-methylphenyl)-5-phenyl-1H-1,2,4-triazolato]iridium(III) (abbreviation: Ir(Mptzl-mp)₃) and tris(1-methyl-5-phenyl-3-propyl-1H-1,2,4-triazolato)iridium(III) (abbreviation: Ir(Prptzl-Me)₃); organometallic iridium complexes having an imidazole skeleton, such as fac-tris[1-(2,6-diisopropylphenyl)-2-phenyl-1H-imidazole]iridium(III) (abbreviation: Ir(iPrpmi)₃) and tris[3-(2,6-dimethylphenyl)-7-methylimidazo[1,2-J]phenanthridinato]iridium(II) (abbreviation: Ir(dmpimpt-Me)₃); and organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), and bis[2-(4′,6′-difluorophenyl)pyridinato-N,C^{2′}]iridium(III) acetylacetonate (abbreviation: FIr(acac)). Among the materials given above, the organic metal iridium complexes including a nitrogen-containing five-membered heterocyclic skeleton, such as a 4H-triazole skeleton, a 1H-triazole skeleton, or an imidazole skeleton have high triplet-excitation energy, reliability, and emission efficiency and are thus especially preferable.

Examples of the substance that has an emission peak in the green or yellow wavelength range include organometallic iridium complexes having a pyrimidine skeleton, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(II) (abbreviation: Ir(tBuppm)₂(acac)), (acetylacetonato)bis[4-(2-norbornyl)-6-phenylpyrimidinato]iridium(III) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), (acetylacetonato)bis{4,6-dimethyl-2-[6-(2,6-dimethylphenyl)-4-pyrimidinyl-κN3]phenyl-κC}iridium(III) (abbreviation: Ir(dmppm-dmp)₂(acac)), (acetylacetonato)bis(4,6-diphenylpyrimidinato)iridium(II) (abbreviation: Ir(dppm)₂(acac)); organometallic iridium complexes having a pyrazine skeleton, such as (acetylacetonato)bis(3,5-dimethyl-2-phenylpyrazinato)iridium(III) (abbreviation: Ir(mppr-Me)₂(acac)) and (acetylacetonato)bis(5-isopropyl-3-methyl-2-phenylpyrazinato)iridium(III) (abbreviation: Ir(mppr-iPr)₂(acac)); organometallic iridium complexes having a pyridine skeleton, such as tris(2-phenylpyridinato-N,C^{2′})iridium(II) (abbreviation: Ir(ppy)₃), bis(2-phenylpyridinato-N,C^{2′})iridium(III) acetylacetonate (abbreviation: Ir(ppy)₂(acac)), bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N,C^{2′})iridium(III) (abbreviation: Ir(pq)₃), and bis(2-phenylquinolinato-N,C^{2′})iridium(III) acetylacetonate (abbreviation: Ir(pq)₂(acac)); organometallic iridium complexes such as bis(2,4-diphenyl-1,3-oxazolato-N,C^{2′})iridium(III) acetylacetonate (abbreviation: Ir(dpo)₂(acac)), bis{2-[4′-(perfluorophenyl)phenyl]pyridinato-N,C^{2′}}iridium(III) acetylacetonate (abbreviation: Ir(p-PF-ph)₂(acac)), and bis(2-phenylbenzothiazolato-N,C^{2′})iridium(III) acetylacetonate (abbreviation: Ir(bt)₂(acac)); and a rare earth metal complex such as tris(acetylacetonato) (monophenanthroline)terbium(II) (abbreviation: Tb(acac)₃(Phen)). Among the materials given above, the organometallic iridium complexes having a pyrimidine skeleton have distinctively high reliability and emission efficiency and are thus particularly preferable.

Examples of the substance that has an emission peak in the yellow or red wavelength range include organometallic iridium complexes having a pyrimidine skeleton, such as (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), and bis[4,6-di(naphthalen-1-yl)pyrimidinato] (dipivaloylmethanato)iridium(III) (abbreviation: Ir(d1npm)₂(dpm)); organometallic iridium complexes having a pyrazine skeleton, such as (acetylacetonato)bis(2,3,5-triphenylpyrazinato)iridium(III) (abbreviation: Ir(tppr)₂(acac)), bis(2,3,5-triphenylpyrazinato) (dipivaloylmethanato)iridium(III) (abbreviation: Ir(tppr)₂(dpm)), and (acetylacetonato)bis[2,3-bis(4-fluorophenyl)quinoxalinato]iridium(III) (abbreviation: Ir(Fdpq)₂(acac)); organometallic iridium complexes having a pyridine skeleton, such as tris(1-phenylisoquinolinato-N,C^{2′})iridium(III) (abbreviation: Ir(piq)₃) and bis(1-phenylisoquinolinato-N,C^{2′})iridium(III) acetylacetonate (abbreviation: Ir(piq)₂(acac)); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato) (monophenanthroline)europium(III) (abbreviation: Eu(DBM)₃(Phen)) and tris[1-(2-thenoyl)-3,3,3-trifluoroacetonato] (monophenanthroline)europium(III) (abbreviation: Eu(TTA)₃(Phen)). Among the materials given above, the organometallic iridium complexes having a pyrimidine skeleton have distinctively high reliability and emission efficiency and are thus particularly preferable. Furthermore, the organometallic iridium complexes having a pyrazine skeleton can provide red light emission with favorable chromaticity.

As an example of the material that can convert the triplet excitation energy into light emission, a thermally activated delayed fluorescent (TADF) material can be given in addition to a phosphorescent compound. Therefore, it is acceptable that the “phosphorescent compound” in the description is replaced with the “thermally activated delayed fluorescence compound”. The thermally activated delayed fluorescence compound is a material having a small difference between the singlet excitation energy level and the triplet excitation energy level and a function of converting triplet excitation energy into singlet excitation energy by reverse intersystem crossing. Thus, the TADF compound can up-convert a triplet excited state into a singlet excited state (i.e., reverse intersystem crossing is possible) using a little thermal energy and efficiently exhibit light emission (fluorescence) from the singlet excited state. The TADF is efficiently obtained under the condition where the difference between the singlet excitation energy level and the triplet excitation energy level is preferably larger than 0 eV and smaller than or equal to 0.3 eV, further preferably larger than 0 eV and smaller than or equal to 0.2 eV, still further preferably larger than 0 eV and smaller than or equal to 0.1 eV.

In the case where the thermally activated delayed fluorescent compound is composed of one kind of material, any of the following materials can be used, for example.

First, a fullerene, a derivative thereof, an acridine derivative such as proflavine, eosin, and the like can be given. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

As the thermally activated delayed fluorescent compound composed of one kind of material, a heterocyclic compound including a π-electron rich heteroaromatic skeleton and a π-electron deficient heteroaromatic skeleton can also be used. Specifically, 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H, 10′H-spiro[acridin-9,9′-anthracen]-10′-one (abbreviation: ACRSA), or the like can be used. The heterocyclic compound is preferable because of having the π-electron rich heteroaromatic skeleton and the π-electron deficient heteroaromatic skeleton, for which the electron-transport property and the hole-transport property are high. Among the π-electron deficient heteroaromatic skeletons, a diazine skeleton (a pyrimidine skeleton, a pyrazine skeleton, or a pyridazine skeleton) and a triazine skeleton are particularly preferable because of their high stability and reliability. Among the π-electron rich heteroaromatic skeletons, an acridine skeleton, a phenoxazine skeleton, a phenothiazine skeleton, a furan skeleton, a thiophene skeleton, and a pyrrole skeleton have high stability and reliability; therefore, one or more of these skeletons are preferably included. As the pyrrole skeleton, an indole skeleton, a carbazole skeleton, or a 9-phenyl-3,3′-bi-9H-carbazole skeleton is particularly preferred. Note that a substance in which the π-electron rich heteroaromatic skeleton is directly bonded to the π-electron deficient heteroaromatic skeleton is particularly preferable because the donor property of the π-electron rich heteroaromatic skeleton and the acceptor property of the π-electron deficient heteroaromatic skeleton are both increased and the difference between the singlet excitation energy level and the triplet excitation energy level becomes small.

The material that exhibits thermally activated delayed fluorescence may be a material that can form a singlet excited state from a triplet excited state by reverse intersystem crossing or may be a combination of a plurality of materials which form an exciplex.

As the host material used for the light-emitting layer 130, hole-transport materials and electron-transport materials can be used.

Although there is no particular limitation on a material that can be used as a host material of the light-emitting layer, for example, any of the following substances can be used for the host material: metal complexes such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: Bphen), bathocuproine (abbreviation: BCP), and 9-[4-(5-phenyl-1,3,4-oxadiazol-2-yl)phenyl]-9H-carbazole (abbreviation: CO11); and aromatic amine compounds such as 4,4′-bis[N-(1-naphthyl)-N-phenylamnino]biphenyl (abbreviation: NPB or α-NPD), N,N′-bis(3-methylphenyl)-N,N′-diphenyl-[1,1′-biphenyl]-4,4′-diamine (abbreviation: TPD), and 4,4′-bis[N-(spiro-9,9′-bifluoren-2-yl)-N-phenylamino]biphenyl (abbreviation: BSPB). In addition, condensed polycyclic aromatic compounds such as anthracene derivatives, phenanthrene derivatives, pyrene derivatives, chrysene derivatives, and dibenzo[g,p]chrysene derivatives can be used. Specific examples of the condensed polycyclic aromatic compound include 9,10-diphenylanthracene (abbreviation: DPAnth), N,N′-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), 2PCAPA, 6,12-dimethoxy-5,11-diphenylchrysene, DBC1, 9-[4-(10-phenyl-9-anthracenyl)phenyl]-9H-Carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), and the like. One or more substances having a wider energy gap than the above-described light-emitting material is preferably selected from these substances and a variety of substances. Moreover, in the case where the light-emitting material is a phosphorescent compound, a substance having triplet excitation energy which is higher than that of the light-emitting material is preferably selected as the host material.

In the case where a plurality of materials are used as the host material of the light-emitting layer, it is preferable to use a combination of two kinds of compounds which form an exciplex. In this case, a variety of carrier-transport materials can be used as appropriate. In order to form an exciplex efficiently, it is particularly preferable to combine an electron-transport material and a hole-transport material.

This is because in the case where the combination of an electron-transport material and a hole-transport material which form an exciplex is used as a host material, the carrier balance between holes and electrons in the light-emitting layer can be easily optimized by adjustment of the mixture ratio of the electron-transport material and the hole-transport material. The optimization of the carrier balance between holes and electrons in the light-emitting layer can prevent a region in which electrons and holes are recombined from existing on one side in the light-emitting layer. By preventing the region in which electrons and holes are recombined from existing on one side, the reliability of the light-emitting element can be improved.

As the electron-transport material, a metal complex containing zinc or aluminum, a π-electron deficient heteroaromatic compound such as a nitrogen-containing heteroaromatic compound, or the like can be used. Specific examples include metal complexes such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); heterocyclic compounds having azole skeletons, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), and 2-[3-(dibenzothiophen-4-yl)phenyl]-1-phenyl-1H-benzimidazole (abbreviation: mDBTBIm-II); heterocyclic compounds having diazine skeletons, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), and 4,6-bis[3-(9H-carbazol-9-yl)phenyl]pyrimidine (abbreviation: 4,6mCzP2Pm); a heterocyclic compound having a triazine skeleton, such as 2-{4-[3-(N-phenyl-9H-carbazol-3-yl)-9H-carbazol-9-yl]phenyl}-4,6-diphenyl-1,3,5-triazine (abbreviation: PCCzPTzn); and heterocyclic compounds having pyridine skeletons, such as 3,5-bis[3-(9H-carbazol-9-yl)phenyl]pyridine (abbreviation: 35DCzPPy) and 1,3,5-tri[3-(3-pyridyl)phenyl]benzene (abbreviation: TmPyPB). Among the above materials, heterocyclic compounds having diazine skeletons and triazine skeletons and heterocyclic compounds having pyridine skeletons have high reliability and are thus preferable. Heterocyclic compounds having diazine (pyrimidine or pyrazine) skeletons and triazine skeletons have a high electron-transport property and contribute to a reduction in drive voltage.

As the hole-transport material, a π-electron rich heteroaromatic compound (e.g., a carbazole derivative or an indole derivative), an aromatic amine compound, or the like can be favorably used. Specific examples include compounds having aromatic amine skeletons, such as 2-[N-(9-phenylcarbazol-3-yl)-N-phenylamino]spiro-9,9′-bifluorene (abbreviation: PCASF), 4,4′,4″-tris[N-(1-naphthyl)-N-phenylamino]triphenylamine (abbreviation: 1′-TNATA), 2,7-bis[N-(4-diphenylaminophenyl)-N-phenylamino]-spiro-9,9′-bifluorene (abbreviation: DPA2SF), N,N′-bis(9-phenylcarbazol-3-yl)-N,N′-diphenylbenzene-1,3-diamine (abbreviation: PCA2B), N-(9,9-dimethyl-2-diphenylamino-9H-fluoren-7-yl)diphenylamine (abbreviation: DPNF), N,N′,N″-triphenyl-N,N′,N″-tris(9-phenylcarbazol-3-yl)benzene-1,3,5-triamine (abbreviation: PCA3B), 2-[N-(9-phenylcarbazol-3-yl)-N-phenylamino]spiro-9,9′-bifluorene (abbreviation: PCASF), 2-[N-(4-diphenylaminophenyl)-N-phenylamino]spiro-9,9′-bifluorene (abbreviation: DPASF), N,N′-bis[4-(carbazol-9-yl)phenyl]-N,N′-diphenyl-9,9-dimethylfluorene-2,7-diamine (abbreviation: YGA2F), 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(4-diphenylaminophenyl)-N-phenylamino]biphenyl (abbreviation: DPAB), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), 3-[N-(9-phenylcarbazol-3-yl)-N-phenylamino]-9-phenylcarbazole (abbreviation: PCzPCA1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), N,N′-bis{4-[bis(3-methylphenyl)amino]phenyl}-N,N′-diphenyl-(1,1′-biphenyl)-4,4′-diamine (abbreviation: DNTPD), 3,6-bis[N-(4-diphenylaminophenyl)-N-(1-naphthyl)amino]-9-phenylcarbazole (abbreviation: PCzTPN2), and 3,6-bis[N-(9-phenylcarbazol-3-yl)-N-phenylamino]-9-phenylcarbazole (abbreviation: PCzPCA2), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamnine (abbreviation: PCBANB), 4,4′-di(1-naphthyl)-4″-(9-phenyl-9H-carbazol-3-yl)triphenylamine (abbreviation: PCBNBB), 3-[N-(1-naphthyl)-N-(9-phenylcarbazol-3-yl)amino]-9-phenylcarbazole (abbreviation: PCzPCN1), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), N-(4-biphenyl)-N-(9,9-dimethyl-9H-fluoren-2-yl)-9-phenyl-9H-carbazol-3-amine (abbreviation: PCBiF), and N-(1,1′-biphenyl-4-yl)-N-[4-(9-phenyl-9H-carbazol-3-yl)phenyl]-9,9-dimethyl-9H-fluor en-2-amine (abbreviation: PCBBiF); compounds having carbazole skeletons, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), and 9-phenyl-9H-3-(9-phenyl-9H-carbazol-3-yl)carbazole (abbreviation: PCCP); compounds having thiophene skeletons, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having furan skeletons, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above-described materials, compounds having aromatic amine skeletons and compounds having carbazole skeletons are preferable because these compounds are highly reliable and have high hole-transport properties to contribute to a reduction in drive voltage.

Note that the combination of the materials which form an exciplex and is used as a host material is not limited to the above-described compounds, as long as they can transport carriers, the combination can form an exciplex, and light emission of the exciplex overlaps with an absorption band on the longest wavelength side in an absorption spectrum of a light-emitting material (an absorption corresponding to the transition of the light-emitting material from the singlet ground state to the singlet excited state), and other materials may be used.

As the host material of the light-emitting layer, a thermally activated delayed fluorescent (TADF) material may be used.

### <<Electron-Transport Layer>>

The electron-transport layer 118 contains a substance having a high electron-transport property. Examples of the substance having a high-electron transport property used for the electron-transport layer 118 include metal complexes having a quinoline ligand, a benzoquinoline ligand, an oxazole ligand, and a thiazole ligand; an oxadiazole derivative; a triazole derivative; a phenanthroline derivative; a pyridine derivative; and a bipyridine derivative. Specific examples include metal complexes such as Alq, Almq₃, BeBq₂, BAlq, ZnPBO, and ZnBTZ. Other examples include heteroaromatic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), 4,4′-bis(5-methylbenzoxazol-2-yl)stilbene (abbreviation: BzOs). Further alternatively, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can be used. The substances described here are mainly substances having an electron mobility of 1×10⁻⁶ cm²/Vs or higher. Note that other substances may also be used for the electron-transport layer 118 as long as their electron-transport properties are higher than their hole-transport properties.

The electron-transport layer 118 is not limited to a single layer, and may include stacked two or more layers containing the aforementioned substances.

Between the electron-transport layer 118 and the light-emitting layer 130, a layer that controls transfer of electron carriers may be provided. This is a layer formed by addition of a small amount of a substance having a high electron-trapping property to a material having a high electron-transport property as described above, and the layer is capable of adjusting the carrier balance by suppressing transfer of electron carriers. Such a structure is very effective in preventing a problem (such as a reduction in element lifetime) caused when electrons pass through the light-emitting layer.

### <<Electron-Injection Layer>>

The electron-injection layer 119 is a layer that includes a substance having a high electron-injection property. For the electron-injection layer 119, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. A rare earth metal compound like erbium fluoride (ErF₃) can also be used. Electride may also be used for the electron-injection layer 119. Examples of the electride include a substance in which electrons are added at high concentration to calcium oxide-aluminum oxide. The electron-injection layer 119 can be formed using the substance that can be used for the electron-transport layer 118.

A composite material in which an organic compound and an electron donor (donor material) are mixed may also be used for the electron-injection layer 119. Such a composite material is excellent in an electron-injection property and an electron-transport property because electrons are generated in the organic compound by the electron donor. In this case, the organic compound is preferably a material that is excellent in transporting the generated electrons. Specifically, the above-listed substances for forming the electron-transport layer 118 (e.g., the metal complexes and heteroaromatic compounds) can be used, for example. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, ytterbium, and the like can be given. Furthermore, an alkali metal oxide and an alkaline earth metal oxide are preferable, and a lithium oxide, a calcium oxide, a barium oxide, and the like can be given. Alternatively, a Lewis base such as magnesium oxide can be used. Further alternatively, an organic compound such as tetrathiafulvalene (abbreviation: TTF) can be used.

Note that the hole-injection layer, the hole-transport layer, the light-emitting layer, the electron-transport layer, and the electron-injection layer described above can each be formed by an evaporation method (including a vacuum evaporation method), an inkjet method, a coating method, a gravure printing method, or the like. Besides the above-mentioned materials, an inorganic compound such as a quantum dot or a high molecular compound (e.g., an oligomer, a dendrimer, or a polymer) may be used in the hole-injection layer, the hole-transport layer, the light-emitting layer, the electron-transport layer, and the electron-injection layer.

The quantum dot may be a colloidal quantum dot, an alloyed quantum dot, a core-shell quantum dot, or a core quantum dot, for example. The quantum dot containing elements belonging to Groups 2 and 16, elements belonging to Groups 13 and 15, elements belonging to Groups 13 and 17, elements belonging to Groups 11 and 17, or elements belonging to Groups 14 and 15 may be used. Alternatively, the quantum dot containing an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

An example of a liquid medium used for a wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

Examples of the high molecular compound that can be used for the light-emitting layer include a phenylenevinylene (PPV) derivative such as poly[2-methoxy-5-(2-ethylhexyloxy)-1,4-phenylenevinylene] (abbreviation: MEH-PPV) or poly(2,5-dioctyl-1,4-phenylenevinylene); a polyfluorene derivative such as poly(9,9-di-n-octylfluorenyl-2,7-diyl) (abbreviation: PF8), poly[(9,9-di-n-octylfluorenyl-2,7-diyl)-alt-(benzo[2,1,3]thiadiazole-4,8-diyl)](abbreviation: F8BT), poly(9,9-di-n-octylfluorenyl-2,7-diyl)-alt-(2,2′-bithiophene-5,5′-diyl)] (abbreviation: F8T2), poly[(9,9-dioctyl-2,7-divinylenefluorenylene)-alt-(9,10-anthracene)], or poly[(9,9-dihexylfluorene-2,7-diyl)-alt-(2,5-dimethyl-1,4-phenylene)]; a polyalkylthiophene (PAT) derivative such as poly(3-hexylthiophen-2,5-diyl) (abbreviation: P3HT); a polyphenylene derivative; or the like. These high molecular compounds or a high molecular compound such as poly(9-vinylcarbazole) (abbreviation: PVK), poly(2-vinylnaphthalene), poly[bis(4-phenyl) (2,4,6-trimethylphenyl)amine] (abbreviation: PTAA) may be doped with a light-emitting low molecular compound and used for the light-emitting layer. As the light-emitting low molecular compound, any of the above-described fluorescent compounds can be used.

### <<Substrate>>

A light-emitting element of one embodiment of the present invention may be formed over a substrate of glass, plastic, or the like. As the way of stacking layers over the substrate, layers may be sequentially stacked from the electrode 101 side or sequentially stacked from the electrode 102 side.

For the substrate over which the light-emitting element of one embodiment of the present invention can be formed, glass, quartz, plastic, or the like can be used, for example. Alternatively, a flexible substrate can be used. The flexible substrate is a substrate that can be bent, such as a plastic substrate made of polycarbonate or polyarylate, for example. A film, an inorganic vapor deposition film, or the like can also be used. Another material may be used as long as the substrate functions as a support in a manufacturing process of the light-emitting elements or optical elements. Another material having a function of protecting the light-emitting elements or optical elements may be used.

In this specification and the like, a light-emitting element can be formed using any of a variety of substrates, for example. The type of a substrate is not limited particularly. Examples of the substrate include a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, cellulose nanofiber (CNF) and paper which include a fibrous material, a base material film, and the like. As an example of a glass substrate, a barium borosilicate glass substrate, an aluminoborosilicate glass substrate, a soda lime glass substrate, or the like can be given. Examples of the flexible substrate, the attachment film, the base material film, and the like are substrates of plastics typified by polyethylene terephthalate (PET), polyethylene naphthalate (PEN), polyether sulfone (PES), and polytetrafluoroethylene (PTFE). Another example is a resin such as acrylic. Alternatively, polypropylene, polyester, polyvinyl fluoride, polyvinyl chloride, or the like can be used. Alternatively, polyamide, polyimide, aramid, epoxy, an inorganic vapor deposition film, paper, or the like can be used.

Alternatively, a flexible substrate may be used as the substrate, and the light-emitting element may be provided directly over the flexible substrate. Alternatively, a separation layer may be provided between the substrate and the light-emitting element. The separation layer can be used when part or the whole of the light-emitting element formed over the separation layer is completed, separated from the substrate, and transferred to another substrate. In such a case, the light-emitting element can be transferred to a substrate having low heat resistance or a flexible substrate as well. For the above separation layer, a stack including inorganic films, which are a tungsten film and a silicon oxide film, or a resin film of polyimide or the like formed over a substrate can be used, for example.

In other words, after the light-emitting element is formed using a substrate, the light-emitting element may be transferred to another substrate. Examples of a substrate to which the light-emitting element is transferred include, in addition to the above-described substrates, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. By using such a substrate, a light-emitting element with high durability, a light-emitting element with high heat resistance, a lightweight light-emitting element, or a thin light-emitting element can be obtained.

The light-emitting element 150 may be formed over an electrode electrically connected to a field-effect transistor (FET), for example, which is formed over any of the above-described substrates. Accordingly, an active matrix display device in which the FET controls the driving of the light-emitting element can be manufactured.

The structure described above in this embodiment can be combined with any of the other embodiments as appropriate.

### Embodiment 2

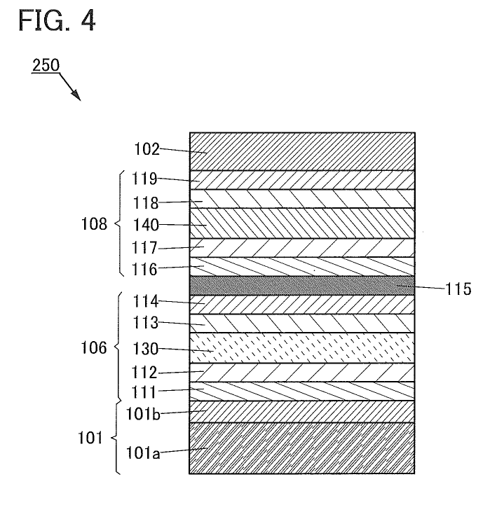

In this embodiment, a light-emitting element having a structure different from that described in Embodiment 1 and light emission mechanisms of the light-emitting element will be described below with reference to FIG. 4. In FIG. 4, a portion having a function similar to that in FIG. 1 is represented by the same hatch pattern as in FIG. 1 and not especially denoted by a reference numeral in some cases. In addition, common reference numerals are used for portions having similar functions, and a detailed description of the portions is omitted in some cases.

### <Structure Example of Light-Emitting Element>

FIG. 4 is a schematic cross-sectional view of a light-emitting element 250.

The light-emitting element 250 illustrated in FIG. 4 includes a plurality of light-emitting units (a light-emitting unit 106 and a light-emitting unit 108 in FIG. 4) between a pair of electrodes (the electrode 101 and the electrode 102). One light-emitting unit has the same structure as the EL layer 100 illustrated in FIG. 1. That is, the light-emitting element 150 illustrated in FIG. 1 includes one light-emitting unit while the light-emitting element 250 includes a plurality of light-emitting units. Note that the electrode 101 functions as an anode and the electrode 102 functions as a cathode in the following description of the light-emitting element 250; however, the functions may be interchanged in the light-emitting element 250.

In the light-emitting element 250 illustrated in FIG. 4, the light-emitting unit 106 and the light-emitting unit 108 are stacked, and a charge-generation layer 115 is provided between the light-emitting unit 106 and the light-emitting unit 108. Note that the light-emitting unit 106 and the light-emitting unit 108 may have the same structure or different structures. For example, it is preferable that the EL layer 100 illustrated in FIG. 1 be used in the light-emitting unit 108.

The light-emitting element 250 includes the light-emitting layer 130 and a light-emitting layer 140. The light-emitting unit 106 includes the hole-injection layer 111, the hole-transport layer 112, an electron-transport layer 113, and an electron-injection layer 114 in addition to the light-emitting layer 130. The light-emitting unit 108 includes a hole-injection layer 116, a hole-transport layer 117, the electron-transport layer 118, and the electron-injection layer 119 in addition to the light-emitting layer 140.

The charge-generation layer 115 may include either an acceptor material that is an electron acceptor or a donor material that is an electron donor. In the case where an acceptor material is used for the charge-generation layer 115, the organic acceptor materials given in Embodiment 1 are preferably used.

The charge-generation layer 115 may have either a structure in which an acceptor material that is an electron acceptor is added to a hole-transport material or a structure in which a donor material that is an electron donor is added to an electron-transport material. Alternatively, both of these structures may be stacked.

In the case where the charge-generation layer 115 contains a composite material of an organic compound and an acceptor material, the composite material that can be used for the hole-injection layer 111 described in Embodiment 1 may be used for the composite material. As the organic compound, a variety of compounds such as an aromatic amine compound, a carbazole compound, an aromatic hydrocarbon, and a high molecular compound (such as an oligomer, a dendrimer, or a polymer) can be used. A substance having a hole mobility of 1×10⁻⁶ cm²/Vs or higher is preferably used as the organic compound. Note that any other substance may be used as long as it has a property of transporting more holes than electrons. Since the composite material of an organic compound and an acceptor material has excellent carrier-injection and carrier-transport properties, low-voltage driving or low-current driving can be realized. Note that when a surface of a light-emitting unit on the anode side is in contact with the charge-generation layer 115 like the light-emitting unit 108, the charge-generation layer 115 can also serve as a hole-injection layer or a hole-transport layer of the light-emitting unit; thus, a hole-injection layer or a hole-transport layer need not be included in the light-emitting unit.

The charge-generation layer 115 may have a stacked structure of a layer containing the composite material of an organic compound and an acceptor material and a layer containing another material. For example, the charge-generation layer 115 may be formed using a combination of a layer containing the composite material of an organic compound and an acceptor material with a layer containing one compound selected from among electron-donating materials and a compound having a high electron-transport property. Furthermore, the charge-generation layer 115 may be formed using a combination of a layer containing the composite material of an organic compound and an acceptor material with a layer including a transparent conductive material.

The charge-generation layer 115 provided between the light-emitting unit 106 and the light-emitting unit 108 may have any structure as long as electrons can be injected into the light-emitting unit on one side and holes can be injected into the light-emitting unit on the other side when a voltage is applied between the electrode 101 and the electrode 102. For example, in FIG. 4, the charge-generation layer 115 injects electrons into the light-emitting unit 106 and holes into the light-emitting unit 108 when a voltage is applied such that the potential of the electrode 101 is higher than that of the electrode 102.

Note that in terms of light extraction efficiency, the charge-generation layer 115 preferably has a visible light transmittance (specifically, a visible light transmittance higher than or equal to 40%). The charge-generation layer 115 functions even if it has lower conductivity than the pair of electrodes (the electrodes 101 and 102). In the case where the conductivity of the charge-generation layer 115 is as high as those of the pair of electrodes, carriers generated in the charge-generation layer 115 flow toward the film surface direction, so that light is emitted in a region where the electrode 101 and the electrode 102 do not overlap, in some cases. To suppress such a defect, the charge-generation layer 115 is preferably formed using a material whose conductivity is lower than those of the pair of electrodes.

Forming the charge-generation layer 115 by using any of the above materials can suppress an increase in drive voltage caused by the stack of the light-emitting layers.

The light-emitting element having two light-emitting units has been described with reference to FIG. 4; however, a similar structure can be applied to a light-emitting element in which three or more light-emitting units are stacked. With a plurality of light-emitting units partitioned by the charge-generation layer between a pair of electrodes as in the light-emitting element 250, it is possible to provide a light-emitting element which can emit light with high luminance with the current density kept low and has a long lifetime. In addition, a light-emitting element with low power consumption can be realized.

When a structure similar to the structure described in Embodiment 1 is used for at least one of the pair of electrodes and at least one of the plurality of units, a light-emitting element with low drive voltage can be provided.

It is particularly preferable that the conductive layer 101b included in the electrode 101 and the hole-injection layer 111 included in the light-emitting unit 106 have the structure described in Embodiment 1. In that case, the light-emitting element 250 has low drive voltage.

Note that the guest materials used in the light-emitting unit 106 and the light-emitting unit 108 may be the same or different. In the case where the same guest material is used for the light-emitting unit 106 and the light-emitting unit 108, the light-emitting element 250 can exhibit high emission luminance at a small current value, which is preferable. In the case where different guest materials are used for the light-emitting unit 106 and the light-emitting unit 108, the light-emitting element 250 can exhibit multi-color light emission, which is preferable. It is particularly favorable to select the guest materials so that white light emission with high color rendering properties or light emission of at least red, green, and blue can be obtained.

Note that the light-emitting units 106 and 108 and the charge-generation layer 115 can be formed by an evaporation method (including a vacuum evaporation method), an ink-jet method, a coating method, gravure printing, or the like.

Note that the structure described in this embodiment can be used in appropriate combination with any of the structures described in the other embodiments.

### Embodiment 3

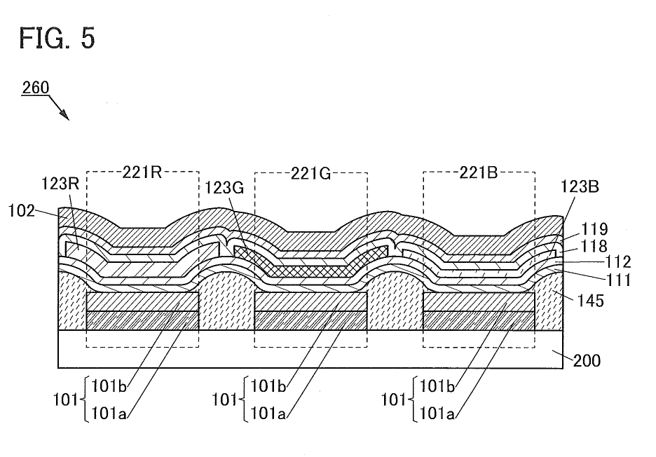

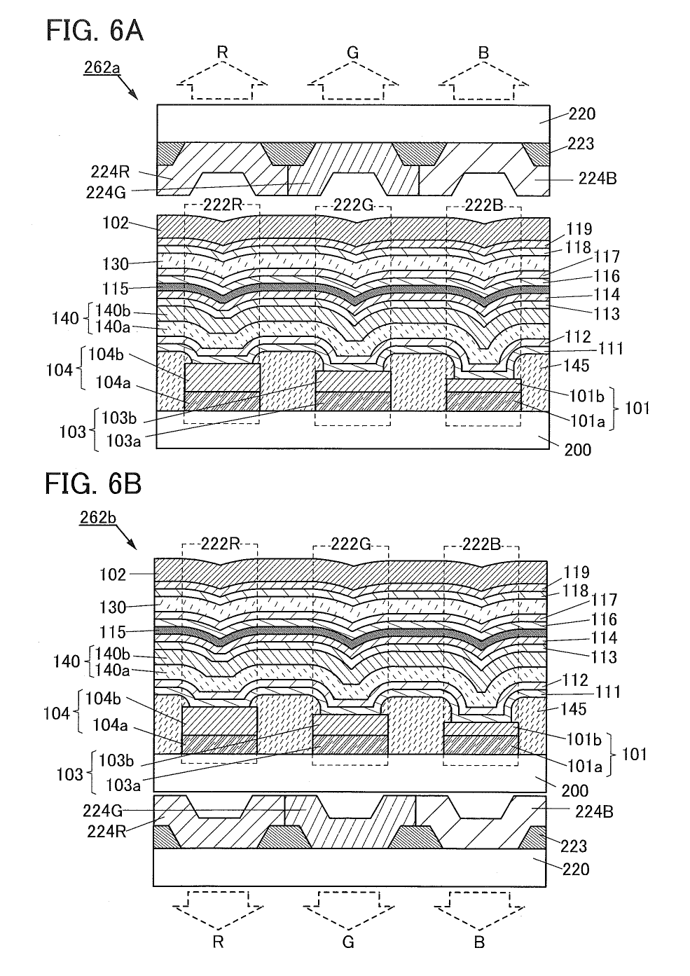

In this embodiment, examples of light-emitting elements having structures different from those described in Embodiments 1 and 2 will be described below with reference to FIG. 5 and FIGS. 6A and 6B.

### Structure Example 1 of Light-Emitting Element

FIG. 5 is a cross-sectional view of a light-emitting element of one embodiment of the present invention. In FIG. 5, a portion having a function similar to that in FIG. 1 is represented by the same hatch pattern as in FIG. 1 and not especially denoted by a reference numeral in some cases. In addition, common reference numerals are used for portions having similar functions, and a detailed description of the portions is omitted in some cases.

A light-emitting element 260 in FIG. 5 may have a bottom-emission structure in which light is extracted through a substrate 200 or may have a top-emission structure in which light emitted from the light-emitting element is extracted in the direction opposite to the substrate 200. However, one embodiment of the present invention is not limited to this structure, and a light-emitting element having a dual-emission structure in which light emitted from the light-emitting element is extracted in both top and bottom directions of the substrate 200 may be used.

In the case where the light-emitting element 260 has a bottom-emission structure, the electrode 101 preferably has a function of transmitting light. In addition, it is preferable that the electrode 102 have a function of reflecting light. In the case where the light-emitting element 260 has a top-emission structure, the electrode 101 preferably has a function of reflecting light. In addition, it is preferable that the electrode 102 have a function of transmitting light.

The light-emitting element 260 includes the electrode 101 and the electrode 102 over the substrate 200. Between the electrodes 101 and 102, a light-emitting layer 123B, a light-emitting layer 123G, and a light-emitting layer 123R are provided. The hole-injection layer 111, the hole-transport layer 112, the electron-transport layer 118, and the electron-injection layer 119 are also provided.

The electrode 101 includes the conductive layer 101a and the conductive layer 101b over and in contact with the conductive layer 101a. It is preferable that the conductive layer 101a have a function of reflecting light and the conductive layer 101b have a function of transmitting light.

For the electrode 101 and the hole-injection layer 111 in this embodiment, structures and materials which are similar to those of the electrode 101 and the hole-injection layer 111 described in Embodiment 1 can be used. In that case, a light-emitting element with low drive voltage can be provided.

In FIG. 5, a partition wall 145 is provided between a region 221B, a region 221G, and a region 221R, which are sandwiched between the electrode 101 and the electrode 102. The partition wall 145 has an insulating property. The partition wall 145 covers end portions of the electrode 101 and has openings overlapping with the electrode. With the partition wall 145, the electrode 101 provided over the substrate 200 in the regions can be divided into island shapes.

Note that the light-emitting layer 123B and the light-emitting layer 123G may overlap with each other in a region where they overlap with the partition wall 145. The light-emitting layer 123G and the light-emitting layer 123R may overlap with each other in a region where they overlap with the partition wall 145. The light-emitting layer 123R and the light-emitting layer 123B may overlap with each other in a region where they overlap with the partition wall 145.

The partition wall 145 has an insulating property and is formed using an inorganic or organic material. Examples of the inorganic material include silicon oxide, silicon oxynitride, silicon nitride oxide, silicon nitride, aluminum oxide, aluminum nitride, and the like. Examples of the organic material include photosensitive resin materials such as an acrylic resin and a polyimide resin.

The light-emitting layers 123R, 123G, and 123B preferably contain light-emitting materials having functions of emitting light of different colors. For example, when the light-emitting layer 123R contains a light-emitting material having a function of emitting red, the region 221R emits red light. When the light-emitting layer 123G contains a light-emitting material having a function of emitting green, the region 221G emits green light. When the light-emitting layer 123B contains a light-emitting material having a function of emitting blue, the region 221B emits blue light. By using the light-emitting element 260 having this structure in a pixel of a display device, a full-color display device can be fabricated. The thicknesses of the light-emitting layers may be the same or different.

One or more of the light-emitting layers 123B, 123G, and 123R may include two or more stacked layers.

When the light-emitting element 260 having the structure described in Embodiment 1 is used in a pixel in a display device as described above, a display device with low drive voltage can be provided. Accordingly, the display device including the light-emitting element 260 can have low power consumption.

By providing a color filter over the electrode through which light is extracted, the color purity of the light-emitting element 260 can be improved. Therefore, the color purity of a display device including the light-emitting element 260 can be improved.

By providing a polarizing plate over the electrode through which light is extracted, the reflection of external light by the light-emitting element 260 can be reduced. Therefore, the contrast ratio of a display device including the light-emitting element 260 can be improved.

Note that for the other components of the light-emitting element 260, the components of the light-emitting elements in Embodiment 1 may be referred to.

### Structure Example 2 of Light-Emitting Element

Next, a structure example different from the light-emitting element illustrated in FIG. 5 will be described below with reference to FIGS. 6A and 6B.

FIGS. 6A and 6B are cross-sectional views each illustrating a light-emitting element of one embodiment of the present invention. In FIGS. 6A and 6B, a portion having a function similar to that in FIG. 5 is represented by the same hatch pattern as that in FIG. 5 and not especially denoted by a reference numeral in some cases. In addition, common reference numerals are used for portions having similar functions, and a detailed description of the portions is omitted in some cases.

FIGS. 6A and 6B illustrate structure examples of a light-emitting element including the light-emitting layer between a pair of electrodes. A light-emitting element 262a illustrated in FIG. 6A has a top-emission structure in which light is extracted in a direction opposite to the substrate 200, and a light-emitting element 262b illustrated in FIG. 6B has a bottom-emission structure in which light is extracted to the substrate 200 side. However, one embodiment of the present invention is not limited to these structures and may have a dual-emission structure in which light emitted from the light-emitting element is extracted in both top and bottom directions with respect to the substrate 200 over which the light-emitting element is formed.

The light-emitting elements 262a and 262b each include the electrode 101, the electrode 102, an electrode 103, and an electrode 104 over the substrate 200. At least the light-emitting layer 130 and the charge-generation layer 115 are provided between the electrode 101 and the electrode 102, between the electrode 102 and the electrode 103, and between the electrode 102 and the electrode 104. The hole-injection layer 111, the hole-transport layer 112, the light-emitting layer 140, the electron-transport layer 113, the electron-injection layer 114, the hole-injection layer 116, the hole-transport layer 117, the electron-transport layer 118, and the electron-injection layer 119 are further provided.

The electrode 101 includes the conductive layer 101a and the conductive layer 101b over and in contact with the conductive layer 101a. The electrode 103 includes a conductive layer 103a and a conductive layer 103b over and in contact with the conductive layer 103a. The electrode 104 includes a conductive layer 104a and a conductive layer 104b over and in contact with the conductive layer 104a.

The light-emitting element 262a illustrated in FIG. 6A and the light-emitting element 262b illustrated in FIG. 6B each include the partition wall 145 between a region 222B sandwiched between the electrode 101 and the electrode 102, a region 222G sandwiched between the electrode 102 and the electrode 103, and a region 222R sandwiched between the electrode 102 and the electrode 104. The partition wall 145 has an insulating property. The partition wall 145 covers end portions of the electrodes 101, 103, and 104 and has openings overlapping with the electrodes. With the partition wall 145, the electrodes provided over the substrate 200 in the regions can be divided into island shapes.

The light-emitting elements 262a and 262b each include a substrate 220 provided with an optical element 224B, an optical element 224G, and an optical element 224R in the direction in which light emitted from the region 222B, light emitted from the region 222G, and light emitted from the region 222R are extracted. The light emitted from each region is emitted outside the light-emitting element through the corresponding optical element. In other words, the light from the region 222B, the light from the region 222G, and the light from the region 222R are emitted through the optical element 224B, the optical element 224G, and the optical element 224R, respectively.

The optical elements 224B, 224G, and 224R each have a function of selectively transmitting light of a particular color out of incident light. For example, the light emitted from the region 222B through the optical element 224B is blue light, the light emitted from the region 222G through the optical element 224G is green light, and the light emitted from the region 222R through the optical element 224R is red light.

For example, a coloring layer (also referred to as a color filter), a band pass filter, a multilayer filter, or the like can be used for the optical elements 224R, 224G, and 224B. Alternatively, color conversion elements can be used as the optical elements. A color conversion element is an optical element that converts incident light into light having a longer wavelength than the incident light. As the color conversion elements, quantum-dot elements can be favorably used. The usage of the quantum-dot can increase color reproducibility of the display device.

A plurality of optical elements may also be stacked over each of the optical elements 224R, 224G, and 224B. As another optical element, a circularly polarizing plate, an anti-reflective film, or the like can be provided, for example. A circularly polarizing plate provided on the side where light emitted from the light-emitting element of the display device is extracted can prevent a phenomenon in which light entering from the outside of the display device is reflected inside the display device and returned to the outside. An anti-reflective film can weaken external light reflected by a surface of the display device. This leads to clear observation of light emitted from the display device.

Note that in FIGS. 6A and 6B, blue light (B), green light (G), and red light (R) emitted from the regions through the optical elements are schematically illustrated by arrows of dashed lines.

A light-blocking layer 223 is provided between the optical elements. The light-blocking layer 223 has a function of blocking light emitted from the adjacent regions. Note that a structure without the light-blocking layer 223 may also be employed.

The light-blocking layer 223 has a function of reducing the reflection of external light. The light-blocking layer 223 has a function of preventing mixture of light emitted from an adjacent light-emitting element. As the light-blocking layer 223, a metal, a resin containing black pigment, carbon black, a metal oxide, a composite oxide containing a solid solution of a plurality of metal oxides, or the like can be used.

For the substrate 200 and the substrate 220 provided with the optical elements, the substrate in Embodiment 1 may be referred to.

Furthermore, the light-emitting elements 262a and 262b have a microcavity structure.

### <<Microcavity Structure>>

Light emitted from the light-emitting layer 130 and the light-emitting layer 140 resonates between a pair of electrodes (e.g., the electrode 101 and the electrode 102). The light-emitting layer 130 and the light-emitting layer 140 are formed at such a position as to intensify light having a desired wavelength among light to be emitted. For example, by adjusting the optical length from a reflective region of the electrode 101 to a light-emitting region of the light-emitting layer 130 and the optical length from a reflective region of the electrode 102 to the light-emitting region of the light-emitting layer 130, the light having a desired wavelength among light emitted from the light-emitting layer 130 can be intensified. Furthermore, by adjusting the optical length from a reflective region of the electrode 101 to a light-emitting region of the light-emitting layer 140 and the optical length from a reflective region of the electrode 102 to the light-emitting region of the light-emitting layer 140, the light having a desired wavelength among light emitted from the light-emitting layer 140 can be intensified. In the case of a light-emitting element in which a plurality of light-emitting layers (here, the light-emitting layers 130 and 140) are stacked, the optical lengths of the light-emitting layers 130 and 140 are preferably optimized.

In each of the light-emitting elements 262a and 262b, by adjusting the thicknesses of the conductive layers (the conductive layer 101b, the conductive layer 103b, and the conductive layer 104b) in each region, the light having a desired wavelength among light emitted from the light-emitting layers 130 and 140 can be intensified. Note that the thickness of at least one of the hole-injection layer 111 and the hole-transport layer 112 may differ between the regions to intensify the light emitted from the light-emitting layers 130 and 140.

For example, in the case where the refractive index of the conductive material having a function of reflecting light in the electrodes 101 to 104 is lower than the refractive index of the light-emitting layer 130 or the light-emitting layer 140, the thickness of the conductive layer 101b of the electrode 101 is adjusted so that the optical length between the electrode 101 and the electrode 102 is m_{B}λ_{B}/2 (m_{B} is a natural number and λ_{B} is the wavelength of light intensified in the region 222B). Similarly, the thickness of the conductive layer 103b of the electrode 103 is adjusted so that the optical length between the electrode 103 and the electrode 102 is m_{G}λ_{G}/2 (m_{G} is a natural number and λ_{G} is the wavelength of light intensified in the region 222G). Furthermore, the thickness of the conductive layer 104b of the electrode 104 is adjusted so that the optical length between the electrode 104 and the electrode 102 is m_{R}λ_{R}/2 (m_{R} is a natural number and λ_{R} is the wavelength of light intensified in the region 222R).

In the above manner, with the microcavity structure, in which the optical length between the pair of electrodes in the respective regions is adjusted, scattering and absorption of light in the vicinity of the electrodes can be suppressed, resulting in high light extraction efficiency. In the above structure, the conductive layers 101b, 103b, and 104b preferably have a function of transmitting light. The materials of the conductive layers 101b, 103b, and 104b may be the same or different. Each of the conductive layers 101b, 103b, and 104b may have a stacked structure of two or more layers.

For the conductive layers 101b, 103b, and 104b in this embodiment, structures and materials which are similar to those of the conductive layer 101b described in Embodiment 1 can be used. Furthermore, for the hole-injection layer 111 in this embodiment, a structure and a material which are similar to those of the hole-injection layer 111 described in Embodiment 1 can be used. In that case, a light-emitting element with low drive voltage can be provided.

Since the light-emitting element 262a illustrated in FIG. 6A has a top-emission structure, it is preferable that the conductive layer 101a, the conductive layer 103a, and the conductive layer 104a have a function of reflecting light. In addition, it is preferable that the electrode 102 have functions of transmitting light and reflecting light.

Since the light-emitting element 262b illustrated in FIG. 6B has a bottom-emission structure, it is preferable that the conductive layer 101a, the conductive layer 103a, and the conductive layer 104a have functions of transmitting light and reflecting light. In addition, it is preferable that the electrode 102 have a function of reflecting light.

In each of the light-emitting elements 262a and 262b, the conductive layers 101a, 103a, and 104a may be formed of different materials or the same material. When the conductive layers 101a, 103a, and 104a are formed of the same material, manufacturing cost of the light-emitting elements 262a and 262b can be reduced. Note that each of the conductive layers 101a, 103a, and 104a may have a stacked structure including two or more layers.

The electrodes 101, 103, and 104 and the hole-injection layer 111 in the light-emitting elements 262a and 262b preferably have structures similar to those described in Embodiment 1. In that case, a light-emitting element with low drive voltage can be provided.

Either or both of the light-emitting layers 130 and 140 may have a stacked structure of two layers like the light-emitting layers 140a and 140b, for example. The two light-emitting layers including two kinds of light-emitting materials (a first light-emitting material and a second light-emitting material) for emitting different colors of light enable light emission of a plurality of colors. It is particularly preferable to select the light-emitting materials of the light-emitting layers so that white light can be obtained by combining light emissions from the light-emitting layer 130 and the light-emitting layer 140.

Either or both of the light-emitting layers 130 and 140 may have a stacked structure of three or more layers, in which a layer not including a light-emitting material may be included.

In the above-described manner, by using the light-emitting element 262a or 262b including the light-emitting layer having any one of the structures described in Embodiment 1 in a pixel in a display device, a display device with low drive voltage can be provided. Accordingly, the display device including the light-emitting element 262a or 262b can have low power consumption.

For the other components of the light-emitting elements 262a and 262b, the components of the light-emitting element 260 or the light-emitting elements described in Embodiments 1 and 2 may be referred to.

Note that the structure described in this embodiment can be used in appropriate combination with any of the structures described in the other embodiments.

### Embodiment 4

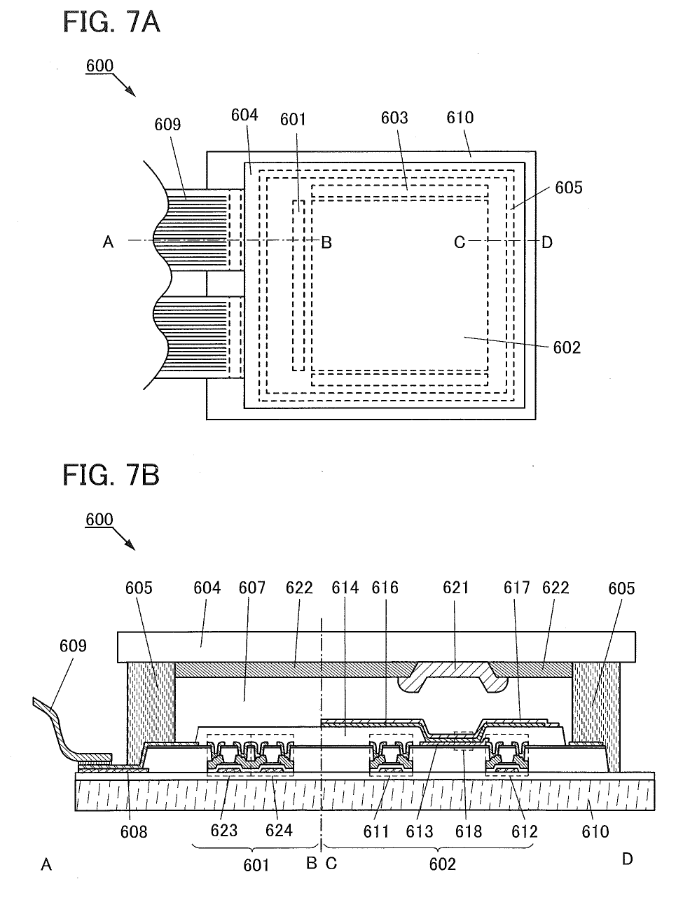

In this embodiment, a display device including a light-emitting element of one embodiment of the present invention will be described with reference to FIGS. 7A and 7B, FIGS. 8A and 8B, and FIGS. 9A and 9B.

### Structure Example 1 of Display Device

FIG. 7A is a top view illustrating a display device 600 and FIG. 7B is a cross-sectional view taken along the dashed-dotted line A-B and the dashed-dotted line C-D in FIG. 7A. The display device 600 includes driver circuit portions (a signal line driver circuit portion 601 and a scan line driver circuit portion 603) and a pixel portion 602. Note that the signal line driver circuit portion 601, the scan line driver circuit portion 603, and the pixel portion 602 have a function of controlling light emission from a light-emitting element.

The display device 600 also includes an element substrate 610, a sealing substrate 604, a sealant 605, a region 607 surrounded by the sealant 605, a lead wiring 608, and an FPC 609.

Note that the lead wiring 608 is a wiring for transmitting signals to be input to the signal line driver circuit portion 601 and the scan line driver circuit portion 603 and for receiving a video signal, a clock signal, a start signal, a reset signal, and the like from the FPC 609 serving as an external input terminal. Although only the FPC 609 is illustrated here, the FPC 609 may be provided with a printed wiring board (PWB).

As the signal line driver circuit portion 601, a CMOS circuit in which an n-channel transistor 623 and a p-channel transistor 624 are combined is formed. As the signal line driver circuit portion 601 or the scan line driver circuit portion 603, various types of circuits such as a CMOS circuit, a PMOS circuit, or an NMOS circuit can be used. Although a driver in which a driver circuit portion is formed and a pixel are formed over the same surface of a substrate in the display device of this embodiment, the driver circuit portion is not necessarily formed over the substrate and can be formed outside the substrate.

The pixel portion 602 includes a switching transistor 611, a current control transistor 612, and a lower electrode 613 electrically connected to a drain of the current control transistor 612. Note that a partition wall 614 is formed to cover end portions of the lower electrode 613. As the partition wall 614, for example, a positive type photosensitive acrylic resin film can be used.

In order to obtain favorable coverage, the partition wall 614 is formed to have a curved surface with curvature at its upper or lower end portion. For example, in the case of using a positive photosensitive acrylic as a material of the partition wall 614, it is preferable that only the upper end portion of the partition wall 614 have a curved surface with curvature (the radius of the curvature being 0.2 m to 3 μm). As the partition wall 614, either a negative photosensitive resin or a positive photosensitive resin can be used.

Note that there is no particular limitation on a structure of each of the transistors (the transistors 611, 612, 623, and 624). For example, a staggered transistor can be used. In addition, there is no particular limitation on the polarity of these transistors. For these transistors, n-channel and p-channel transistors may be used, or either n-channel transistors or p-channel transistors may be used, for example. Furthermore, there is no particular limitation on the crystallinity of a semiconductor film used for the transistors. For example, an amorphous semiconductor film or a crystalline semiconductor film may be used. Examples of a semiconductor material include Group 14 semiconductors (e.g., a semiconductor including silicon), compound semiconductors (including oxide semiconductors), organic semiconductors, and the like. For example, it is preferable to use an oxide semiconductor that has an energy gap of 2 eV or more, preferably 2.5 eV or more, and more preferably 3 eV or more, for the transistors, so that the off-state current of the transistors can be reduced. Examples of the oxide semiconductor include an In—Ga oxide, and an In-M-Zn oxide (M represents one or more of Al, Si, Ti, Ga, Y, Zr, La, Ce, Sn, Nd, and Hf).

Note that in the above-described transistors, an oxide semiconductor layer including a channel region of the transistor and the conductive layer of the lower electrode 613 are favorably formed with oxides including the same elements. In other words, the oxide semiconductor layer used for the channel region of the transistor preferably includes In and M (M represents one or more of Al, Si, Ti, Ga, Y, Zr, La, Ce, Nd, and Hf). In addition, it is particularly preferable to use the same materials for the oxide semiconductor layer and the conductive layer.

An EL layer 616 and an upper electrode 617 are formed over the lower electrode 613. Here, the lower electrode 613 functions as an anode and the upper electrode 617 functions as a cathode.

In addition, the EL layer 616 is formed by any of various methods including an evaporation method (including a vacuum evaporation method) with an evaporation mask, a droplet discharge method (also referred to as an ink-jet method), a coating method such as a spin coating method, and a gravure printing method. As another material included in the EL layer 616, a low molecular compound or a high molecular compound (including an oligomer or a dendrimer) may be used.

Note that a light-emitting element 618 is formed with the lower electrode 613, the EL layer 616, and the upper electrode 617. The light-emitting element 618 preferably has any of the structures described in Embodiments 1 to 3. In the case where the pixel portion includes a plurality of light-emitting elements, the pixel portion may include both any of the light-emitting elements described in Embodiments 1 to 3 and a light-emitting element having a different structure.

When the sealing substrate 604 and the element substrate 610 are attached to each other with the sealant 605, the light-emitting element 618 is provided in the region 607 surrounded by the element substrate 610, the sealing substrate 604, and the sealant 605. The region 607 is filled with a filler. In some cases, the region 607 is filled with an inert gas (nitrogen, argon, or the like) or filled with an ultraviolet curable resin or a thermosetting resin which can be used for the sealant 605. For example, a polyvinyl chloride (PVC) based resin, an acrylic-based resin, a polyimide-based resin, an epoxy-based resin, a silicone-based resin, a polyvinyl butyral (PVB) based resin, or an ethylene vinyl acetate (EVA) based resin can be used. It is preferable that the sealing substrate be provided with a recessed portion and a desiccant be provided in the recessed portion, in which case deterioration due to influence of moisture can be inhibited.

An optical element 621 is provided below the sealing substrate 604 to overlap with the light-emitting element 618. A light-blocking layer 622 is provided below the sealing substrate 604. The structures of the optical element 621 and the light-blocking layer 622 can be the same as those of the optical element and the light-blocking layer in Embodiment 3, respectively.

An epoxy-based resin or glass frit is preferably used for the sealant 605. It is preferable that such a material do not transmit moisture or oxygen as much as possible. As the sealing substrate 604, a glass substrate, a quartz substrate, or a plastic substrate formed of fiber reinforced plastic (FRP), poly(vinyl fluoride) (PVF), polyester, acrylic, or the like can be used.

In the above-described manner, a display device including any of the light-emitting elements and the optical elements which are described in Embodiments 1 to 3 can be obtained.

### Structure Example 2 of Display Device

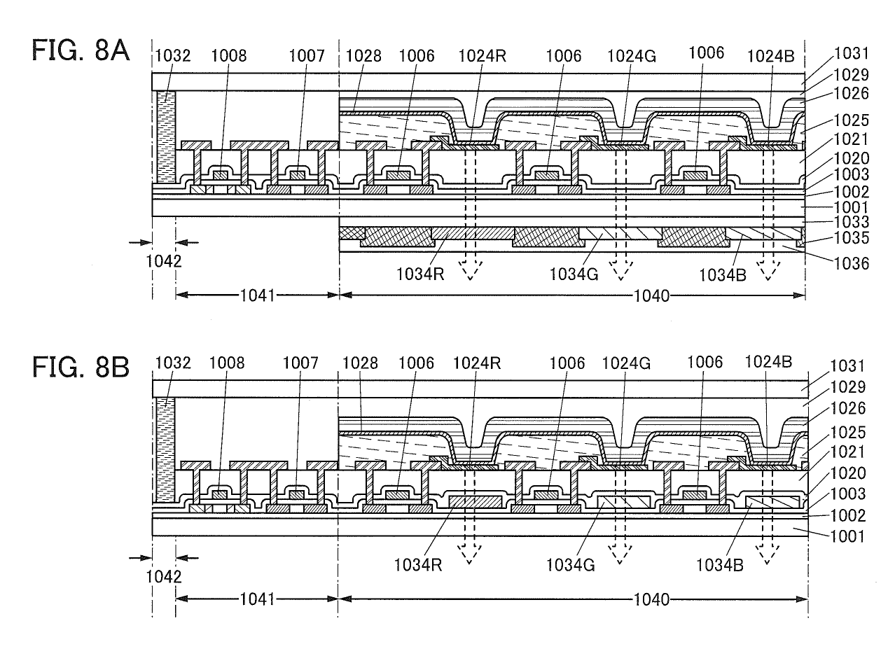

Next, another example of the display device will be described with reference to FIGS. 8A and 8B. Note that FIGS. 8A and 8B are each a cross-sectional view illustrating a display device of one embodiment of the present invention.

In FIG. 8A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, lower electrodes 1024R, 1024G, and 1024B of light-emitting elements, a partition wall 1025, an EL layer 1028, an upper electrode 1026 of the light-emitting elements, a sealing layer 1029, a sealing substrate 1031, a sealant 1032, and the like are illustrated.

In FIG. 8A, examples of the optical elements, coloring layers (a red coloring layer 1034R, a green coloring layer 1034G, and a blue coloring layer 1034B) are provided on a transparent base material 1033. Furthermore, a light-blocking layer 1035 may be provided. The transparent base material 1033 provided with the coloring layers and the light-blocking layer is positioned and fixed to the substrate 1001. Note that the coloring layers and the light-blocking layer are covered with an overcoat layer 1036. In the structure in FIG. 8A, red light, green light, and blue light pass through the coloring layers, and thus an image can be displayed with the use of pixels of three colors.

FIG. 8B illustrates an example in which, as examples of the optical elements, the coloring layers (the red coloring layer 1034R, the green coloring layer 1034G, and the blue coloring layer 1034B) are provided between the gate insulating film 1003 and the first interlayer insulating film 1020. As in this structure, the coloring layers may be provided between the substrate 1001 and the sealing substrate 1031.

As examples of the optical elements, the coloring layers (the red coloring layer 1034R, the green coloring layer 1034G, and the blue coloring layer 1034B) are provided between the first interlayer insulating film 1020 and the second interlayer insulating film 1021.

The above-described display device has a structure in which light is extracted from the substrate 1001 side where the transistors are formed (a bottom-emission structure), but may have a structure in which light is extracted from the sealing substrate 1031 side (a top-emission structure).

### Structure Example 3 of Display Device

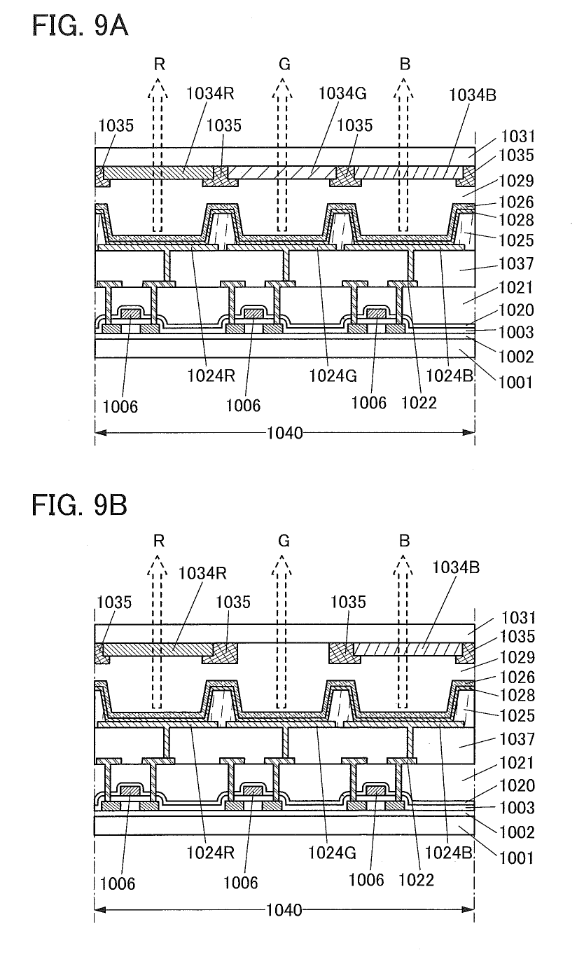

FIGS. 9A and 9B are each an example of a cross-sectional view of a display device having a top-emission structure. Note that FIGS. 9A and 9B are each a cross-sectional view illustrating the display device of one embodiment of the present invention, and the driver circuit portion 1041, the peripheral portion 1042, and the like, which are illustrated in FIGS. 8A and 8B, are not illustrated therein.

In that case, a substrate which does not transmit light can be used as the substrate 1001. The process up to the step of forming a connection electrode which connects the transistor and the anode of the light-emitting element is performed in a manner similar to that of the display device having a bottom-emission structure. Then, a third interlayer insulating film 1037 is formed to cover an electrode 1022. This insulating film may have a planarization function. The third interlayer insulating film 1037 can be formed using a material similar to that of the second interlayer insulating film, or can be formed using various other materials.

The lower electrodes 1024R, 1024G, and 1024B of the light-emitting elements each function as an anode here, but may function as a cathode. Furthermore, in the case of a display device having a top-emission structure as illustrated in FIGS. 9A and 9B, the lower electrodes 1024R, 1024G, and 1024B preferably have a function of reflecting light. The lower electrodes 1024R, 1024G, and 1024B and the EL layer 1028 can have structures similar to those of the electrode 101 and the EL layer 100 in Embodiment 1, respectively. In other words, it is preferable that the lower electrodes 1024R, 1024G, and 1024B include a first conductive layer and a second conductive layer over and in contact with the first conductive layer, that the first conductive layer have a function of reflecting light, and that the second conductive layer have a function of transmitting light. The upper electrode 1026 is provided over the EL layer 1028. It is preferable that the upper electrode 1026 have a function of reflecting light and a function of transmitting light and that a microcavity structure be used between the upper electrode 1026 and the lower electrodes 1024R, 1024G, and 1024B, in which case the intensity of light having a specific wavelength is increased.

In the case of a top-emission structure as illustrated in FIG. 9A, sealing can be performed with the sealing substrate 1031 on which the coloring layers (the red coloring layer 1034R, the green coloring layer 1034G, and the blue coloring layer 1034B) are provided. The sealing substrate 1031 may be provided with the light-blocking layer 1035 which is positioned between pixels. Note that a light-transmitting substrate is favorably used as the sealing substrate 1031.

FIG. 9A illustrates the structure provided with the light-emitting elements and the coloring layers for the light-emitting elements as an example; however, the structure is not limited thereto. For example, as shown in FIG. 9B, a structure including the red coloring layer 1034R and the blue coloring layer 1034B but not including a green coloring layer may be employed to achieve full color display with the three colors of red, green, and blue. The structure as illustrated in FIG. 9A where the light-emitting elements are provided with the coloring layers is effective to suppress reflection of external light. In contrast, the structure as illustrated in FIG. 9B where the light-emitting elements are provided with the red coloring layer and the blue coloring layer but not with the green coloring layer is effective in reducing power consumption because of small energy loss of light emitted from the green light-emitting element.

Although a display device including sub-pixels of three colors (red, green, and blue) is described above, the number of colors of sub-pixels may be four (red, green, blue, and yellow, or red, green, blue, and white). In this case, a coloring layer can be used which has a function of transmitting yellow light or a function of transmitting light of a plurality of colors selected from blue, green, yellow, and red. When the coloring layer can transmit light of a plurality of colors selected from blue, green, yellow, and red, light passing through the coloring layer may be white light. Since the light-emitting element which exhibits yellow or white light has high emission efficiency, the display device having such a structure can have lower power consumption.

Furthermore, in the display device 600 shown in FIGS. 7A and 7B, a sealing layer may be formed in the region 607 which is surrounded by the element substrate 610, the sealing substrate 604, and the sealant 605. For the sealing layer, a resin such as a polyvinyl chloride (PVC) based resin, an acrylic-based resin, a polyimide-based resin, an epoxy-based resin, a silicone-based resin, a polyvinyl butyral (PVB) based resin, or an ethylene vinyl acetate (EVA) based resin can be used. Alternatively, an inorganic material such as silicon oxide, silicon oxynitride, silicon nitride oxide, silicon nitride, aluminum oxide, or aluminum nitride can be used. The formation of the sealing layer in the region 607 can prevent deterioration of the light-emitting element 618 due to impurities such as water, which is preferable. Note that in the case where the sealing layer is formed, the sealant 605 is not necessarily provided.

When the sealing layer has a multilayer structure, the impurities such as water can be effectively prevented from entering the light-emitting element 618 which is inside the display device from the outside of the display device 600. In the case where the sealing layer has a multilayer structure, a resin and an inorganic material are preferably stacked.

The structures described in this embodiment can be combined as appropriate with any of the other structures in this embodiment and the other embodiments.

### Embodiment 5

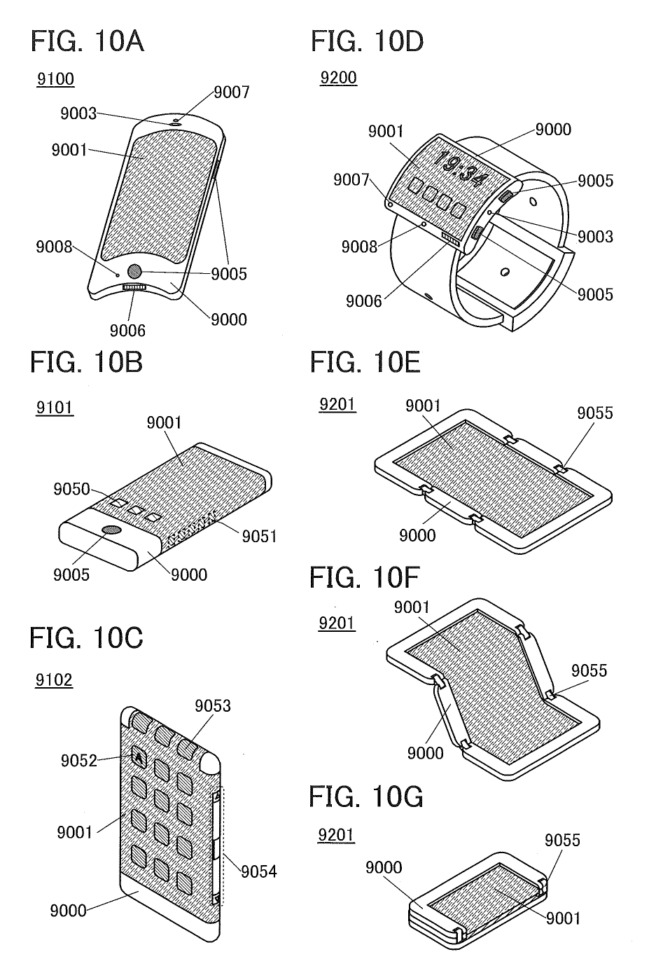

In this embodiment, electronic devices, a light-emitting device, and lighting devices each including the light-emitting element of one embodiment of the present invention will be described with reference to FIGS. 10A to 10G, FIGS. 11A to 11C, and FIG. 12.

### <Electronic Device>

FIGS. 10A to 10G show electronic devices. These electronic devices can each include a housing 9000, a display portion 9001, a speaker 9003, operation keys 9005 (including a power switch or an operation switch), a connection terminal 9006, a sensor 9007 (a sensor having a function of measuring or sensing force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like. In addition, the sensor 9007 may have a function of measuring biological information like a pulse sensor and a finger print sensor.

The electronic devices illustrated in FIGS. 10A to 10G can have a variety of functions, for example, a function of displaying a variety of data (a still image, a moving image, a text image, and the like) on the display portion, a touch sensor function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, a function of reading a program or data stored in a memory medium and displaying the program or data on the display portion, and the like. Note that the electronic devices illustrated in FIGS. 10A to 10G can have a variety of functions without limitation to the above functions. Although not illustrated in FIGS. 10A to 10G, the electronic devices may include a plurality of display portions. The electronic devices may have a camera or the like and a function of taking a still image, a function of taking a moving image, a function of storing the taken image in a memory medium (an external memory medium or a memory medium incorporated in the camera), a function of displaying the taken image on the display portion, or the like.

The electronic devices in FIGS. 10A to 10G will be described in detail below.

FIG. 10A is a perspective view of a portable information terminal 9100. The display portion 9001 of the portable information terminal 9100 is flexible. Therefore, the display portion 9001 can be incorporated along a curved surface of a curved housing 9000. In addition, the display portion 9001 includes a touch sensor, and operation can be performed by touching the screen with a finger, a stylus, or the like. For example, when an icon displayed on the display portion 9001 is touched, an application can be started.

FIG. 10B is a perspective view illustrating a portable information terminal 9101. The portable information terminal 9101 functions as, for example, one or more of a telephone set, a notebook, and an information browsing system. Specifically, the portable information terminal can be used as a smartphone. Note that the speaker 9003, the connection terminal 9006, the sensor 9007, and the like, which are not illustrated in the drawing in FIG. 10A, can be positioned in the portable information terminal 9101 as in the portable information terminal 9100 illustrated in FIG. 10A. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include display indicating reception of an incoming email, social networking service (SNS) message, call, and the like; the title and sender of an email and SNS message; the date; the time; remaining battery; and display indicating the strength of a received signal such as a radio wave. Instead of the information 9051, the operation buttons 9050 or the like may be displayed on the position where the information 9051 is displayed.

As a material of the housing 9000, for example, an alloy, plastic, or ceramic can be used. As a plastic, a reinforced plastic can also be used. A carbon fiber reinforced plastic (CFRP), which is a kind of reinforced plastic, has advantages of being lightweight and corrosion-free. Other examples of the reinforced plastic include one including glass fiber and one including aramid fiber. As the alloy, an aluminum alloy and a magnesium alloy can be given. In particular, amorphous alloy (also referred to as metal glass) containing zirconium, copper, nickel, and titanium is superior in terms of high elastic strength. This amorphous alloy includes a glass transition region at room temperature, which is also referred to as a bulk-solidifying amorphous alloy and substantially has an amorphous atomic structure. By a solidification casting method, an alloy material is put in a mold of at least part of the housing and coagulated so that the part of the housing is formed using a bulk-solidifying amorphous alloy. The amorphous alloy may include beryllium, silicon, niobium, boron, gallium, molybdenum, tungsten, manganese, iron, cobalt, yttrium, vanadium, phosphorus, carbon, or the like in addition to zirconium, copper, nickel, and titanium. The amorphous alloy may be formed by a vacuum evaporation method, a sputtering method, an electroplating method, an electroless plating method, or the like instead of the solidification casting method. The amorphous alloy may include a microcrystal or a nanocrystal as long as a state without a long-range order (a periodic structure) is maintained as a whole. Note that the term alloy refer to both a complete solid solution alloy which has a single solid phase structure and a partial solution that has two or more phases. The housing 9000 using the amorphous alloy can have high elastic strength. Even if the portable information terminal 9101 is dropped and the impact causes temporary deformation, the use of the amorphous alloy in the housing 9000 allows a return to the original shape; thus, the impact resistance of the portable information terminal 9101 can be improved.

FIG. 10C is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call.

FIG. 10D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is bent, and images can be displayed on the bent display surface. The portable information terminal 9200 can employ near field communication that is a communication method based on an existing communication standard. In that case, for example, mutual communication between the portable information terminal 9200 and a headset capable of wireless communication can be performed, and thus hands-free calling is possible. The portable information terminal 9200 includes the connection terminal 9006, and data can be directly transmitted to and received from another information terminal via a connector. Power charging through the connection terminal 9006 is possible. Note that the charging operation may be performed by wireless power feeding without using the connection terminal 9006.

FIGS. 10E, 10F, and 10G are perspective views of a foldable portable information terminal 9201. FIG. 10E is a perspective view illustrating the portable information terminal 9201 that is opened. FIG. 10F is a perspective view illustrating the portable information terminal 9201 that is shifted from the opened state to the folded state or from the folded state to the opened state. FIG. 10G is a perspective view illustrating the portable information terminal 9201 that is folded. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from the opened state to the folded state. For example, the portable information terminal 9201 can be bent with a radius of curvature of greater than or equal to 1 mm and less than or equal to 150 mm.

Examples of electronic devices are a television set (also referred to as a television or a television receiver), a monitor of a computer or the like, a digital camera, a digital video camera, a digital photo frame, a mobile phone handset (also referred to as a mobile phone or a mobile phone device), a goggle-type display (head mounted display), a portable game machine, a portable information terminal, an audio reproducing device, and a large-sized game machine such as a pachinko machine.

Furthermore, the electronic device of one embodiment of the present invention may include a secondary battery. It is preferable that the secondary battery be capable of being charged by non-contact power transmission.

Examples of the secondary battery include a lithium ion secondary battery such as a lithium polymer battery using a gel electrolyte (lithium ion polymer battery), a lithium-ion battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display an image, data, or the like on a display portion. When the electronic device includes a secondary battery, the antenna may be used for non-contact power transmission.

The electronic device or the lighting device of one embodiment of the present invention has flexibility and therefore can be incorporated along a curved inside/outside wall surface of a house or a building or a curved interior/exterior surface of a car. For example, the electronic device or the lighting device can be used for lighting for a dashboard, a windshield, a ceiling, and the like of a car.

### <Light-Emitting Device>

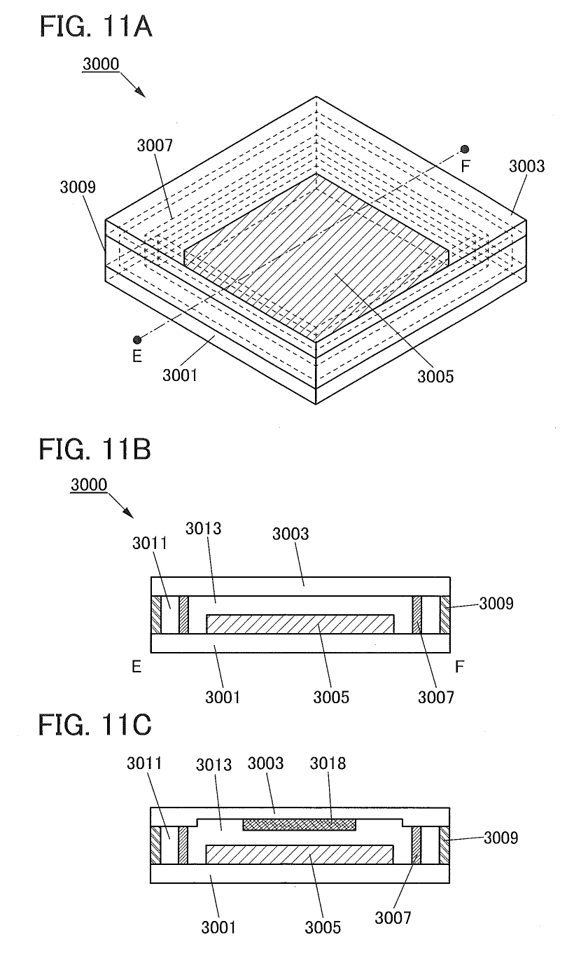

FIG. 11A is a perspective view of a light-emitting device 3000 shown in this embodiment, and FIG. 11B is a cross-sectional view along the dashed-dotted line E-F in FIG. 11A. Note that in FIG. 11A, some components are illustrated by broken lines in order to avoid complexity of the drawing.

The light-emitting device 3000 illustrated in FIGS. 11A and 11B includes a substrate 3001, a light-emitting element 3005 over the substrate 3001, a first sealing region 3007 provided around the light-emitting element 3005, and a second sealing region 3009 provided around the first sealing region 3007.

Light is emitted from the light-emitting element 3005 through one or both of the substrate 3001 and a substrate 3003. In FIGS. 11A and 11B, a structure in which light is emitted from the light-emitting element 3005 to the lower side (the substrate 3001 side) is illustrated.

As illustrated in FIGS. 11A and 11B, the light-emitting device 3000 has a double sealing structure in which the light-emitting element 3005 is surrounded by the first sealing region 3007 and the second sealing region 3009. With the double sealing structure, entry of impurities (e.g., water, oxygen, and the like) from the outside into the light-emitting element 3005 can be favorably suppressed. Note that it is not necessary to provide both the first sealing region 3007 and the second sealing region 3009. For example, only the first sealing region 3007 may be provided.

Note that in FIG. 11B, the first sealing region 3007 and the second sealing region 3009 are each provided in contact with the substrate 3001 and the substrate 3003. However, without limitation to such a structure, for example, one or both of the first sealing region 3007 and the second sealing region 3009 may be provided in contact with an insulating film or a conductive layer provided on the substrate 3001. Alternatively, one or both of the first sealing region 3007 and the second sealing region 3009 may be provided in contact with an insulating film or a conductive layer provided on the substrate 3003.

The substrate 3001 and the substrate 3003 can have structures similar to those of the substrate 200 and the substrate 220 described in the above embodiment, respectively. The light-emitting element 3005 can have a structure similar to that of any of the light-emitting elements described in the above embodiments.

For the first sealing region 3007, a material containing glass (e.g., a glass frit, a glass ribbon, and the like) can be used. For the second sealing region 3009, a material containing a resin can be used. With the use of the material containing glass for the first sealing region 3007, productivity and a sealing property can be improved. Moreover, with the use of the material containing a resin for the second sealing region 3009, impact resistance and heat resistance can be improved. However, the materials used for the first sealing region 3007 and the second sealing region 3009 are not limited thereto, and the first sealing region 3007 may be formed using the material containing a resin and the second sealing region 3009 may be formed using the material containing glass.

The glass frit may contain, for example, magnesium oxide, calcium oxide, strontium oxide, barium oxide, cesium oxide, sodium oxide, potassium oxide, boron oxide, vanadium oxide, zinc oxide, tellurium oxide, aluminum oxide, silicon dioxide, lead oxide, tin oxide, phosphorus oxide, ruthenium oxide, rhodium oxide, iron oxide, copper oxide, manganese dioxide, molybdenum oxide, niobium oxide, titanium oxide, tungsten oxide, bismuth oxide, zirconium oxide, lithium oxide, antimony oxide, lead borate glass, tin phosphate glass, vanadate glass, or borosilicate glass. The glass frit preferably contains at least one kind of transition metal to absorb infrared light.

As the above glass frits, for example, a frit paste is applied to a substrate and is subjected to heat treatment, laser light irradiation, or the like. The frit paste contains the glass frit and a resin (also referred to as a binder) diluted by an organic solvent. Note that an absorber which absorbs light having the wavelength of laser light may be added to the glass frit. For example, an Nd:YAG laser or a semiconductor laser is preferably used as the laser. The shape of laser light may be circular or quadrangular.

As the above material containing a resin, for example, polyester, polyolefin, polyamide (e.g., nylon or aramid), polyimide, polycarbonate, or an acrylic resin, polyurethane, or an epoxy resin can be used. Alternatively, a material that includes a resin having a siloxane bond such as silicone can be used.

Note that in the case where the material containing glass is used for one or both of the first sealing region 3007 and the second sealing region 3009, the material containing glass preferably has a thermal expansion coefficient close to that of the substrate 3001. With the above structure, generation of a crack in the material containing glass or the substrate 3001 due to thermal stress can be suppressed.

For example, the following advantageous effect can be obtained in the case where the material containing glass is used for the first sealing region 3007 and the material containing a resin is used for the second sealing region 3009.

The second sealing region 3009 is provided closer to an outer portion of the light-emitting device 3000 than the first sealing region 3007 is. In the light-emitting device 3000, distortion due to external force or the like increases toward the outer portion. Thus, the outer portion of the light-emitting device 3000 where a larger amount of distortion is generated, that is, the second sealing region 3009 is sealed using the material containing a resin and the first sealing region 3007 provided on an inner side of the second sealing region 3009 is sealed using the material containing glass, whereby the light-emitting device 3000 is less likely to be damaged even when distortion due to external force or the like is generated.

Furthermore, as illustrated in FIG. 11B, a first region 3011 corresponds to the region surrounded by the substrate 3001, the substrate 3003, the first sealing region 3007, and the second sealing region 3009. A second region 3013 corresponds to the region surrounded by the substrate 3001, the substrate 3003, the light-emitting element 3005, and the first sealing region 3007.

The first region 3011 and the second region 3013 are preferably filled with, for example, an inert gas such as a rare gas or a nitrogen gas. Alternatively, the first region 3011 and the second region 3013 are preferably filled with a resin such as an acrylic resin or an epoxy resin. Note that for the first region 3011 and the second region 3013, a reduced pressure state is preferred to an atmospheric pressure state.

FIG. 11C illustrates a modification example of the structure in FIG. 11B. FIG. 11C is a cross-sectional view illustrating the modification example of the light-emitting device 3000.

FIG. 11C illustrates a structure in which a desiccant 3018 is provided in a recessed portion provided in part of the substrate 3003. The other components are the same as those of the structure illustrated in FIG. 11B.

As the desiccant 3018, a substance which adsorbs moisture and the like by chemical adsorption or a substance which adsorbs moisture and the like by physical adsorption can be used. Examples of the substance that can be used as the desiccant 3018 include alkali metal oxides, alkaline earth metal oxides (e.g., calcium oxide, barium oxide, and the like), sulfate, metal halides, perchlorate, zeolite, silica gel, and the like.

### <Lighting Device>

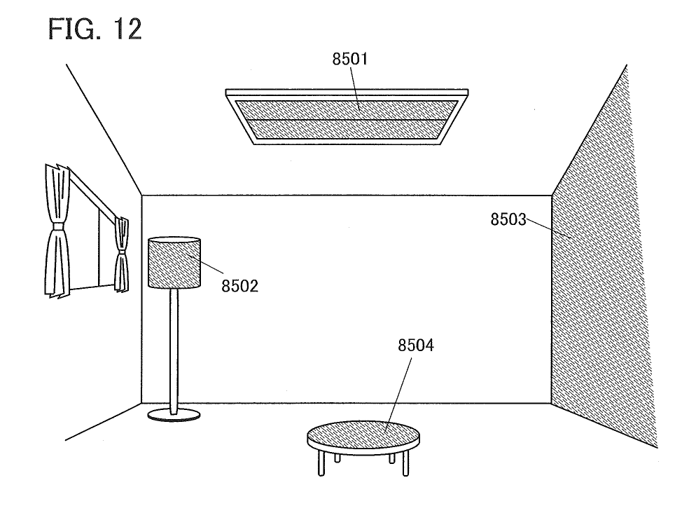

FIG. 12 illustrates an example in which the light-emitting element is used for an indoor lighting device 8501. Since the light-emitting element can have a larger area, a lighting device having a large area can also be formed. In addition, a lighting device 8502 in which a light-emitting region has a curved surface can also be formed with the use of a housing with a curved surface. The light-emitting element described in this embodiment is in the form of a thin film, which allows the housing to be designed more freely. Therefore, the lighting device can be elaborately designed in a variety of ways. Furthermore, a wall of the room may be provided with a large-sized lighting device 8503. Touch sensors may be provided in the lighting devices 8501, 8502, and 8503 to control the power on/off of the lighting devices.

Moreover, when the light-emitting element is used on the surface side of a table, a lighting device 8504 which has a function as a table can be obtained. When the light-emitting element is used as part of other furniture, a lighting device which has a function as the furniture can be obtained.

As described above, display modules, light-emitting devices, electronic devices, and lighting devices can be obtained by application of the light-emitting element of one embodiment of the present invention. Note that the light-emitting element can be used for electronic devices in a variety of fields without being limited to the lighting devices and the electronic devices described in this embodiment.

The structure described in this embodiment can be combined with any of the structures described in the other embodiments as appropriate.

### Example 1

In this example, results of measuring energy levels of oxides and energy levels of organic acceptor materials of one embodiment of the present invention are shown.

### <Energy Levels of Oxides>

An In—Ga—Zn oxide was formed over each substrate for a conductive layer. The atomic ratios of metal elements of sputtering targets for the In—Ga—Zn oxides are In:Ga:Zn=1:1:1, In:Ga:Zn=1:3:2, In:Ga:Zn=1:3:4, In:Ga:Zn=1:3:6, In:Ga:Zn=1:4:5, and In:Ga:Zn=4:2:4.1.

The energy gaps of the oxides were measured using a spectroscopic ellipsometer (UT-300 manufactured by HORIBA JOBIN YVON S.A.S.). The difference between the vacuum level and the energy level of the valence band maximum was measured using an ultraviolet photoelectron spectroscopy (UPS) device (VersaProbe manufactured by ULVAC-PHI, Inc.). The electron affinity that is the difference between the vacuum level and the energy level of the conduction band minimum was calculated by subtracting the bandgap from the difference between the vacuum level and the energy level of the valence band maximum.

An In—Ga—Zn oxide which was formed using a target having an atomic ratio of In:Ga:Zn=1:1:1 had an energy gap of approximately 3.2 eV and an electron affinity of approximately 4.7 eV. An In—Ga—Zn oxide which was formed using a target having an atomic ratio of In:Ga:Zn=1:3:2 had an energy gap of approximately 3.5 eV and an electron affinity of approximately 4.5 eV. An In—Ga—Zn oxide which was formed using a target having an atomic ratio of In:Ga:Zn=1:3:4 had an energy gap of approximately 3.4 eV and an electron affinity of approximately 4.5 eV. An In—Ga—Zn oxide which was formed using a target having an atomic ratio of In:Ga:Zn=1:3:6 had an energy gap of approximately 3.3 eV and an electron affinity of approximately 4.5 eV. An In—Ga—Zn oxide which was formed using a target having an atomic ratio of In:Ga:Zn=1:4:5 had an energy gap of approximately 3.6 eV and an electron affinity of approximately 4.3 eV. An In—Ga—Zn oxide which was formed using a target having an atomic ratio of In:Ga:Zn=4:2:4.1 had an energy gap of approximately 3.0 eV and an electron affinity of approximately 4.4 eV.

### <Energy Levels of Organic Acceptor Materials>

The electrochemical characteristics (oxidation reaction characteristics and reduction reaction characteristics) of HAT-CN which is an organic acceptor material were measured by cyclic voltammetry (CV) measurement. Note that for the measurement, an electrochemical analyzer (ALS model 600A or 600C, produced by BAS Inc.) was used, and the measurement was performed on a solution obtained by dissolving the compound in N,N-dimethylformamnide (abbreviation: DMF). The oxidation peak potential and the reduction peak potential were measured by changing the potential of a working electrode with respect to the reference electrode within an appropriate range. In addition, the HOMO and LUMO levels of the compound were obtained from the estimated redox potential of the reference electrode of −4.94 eV and the obtained peak potentials.

From the CV measurement results, the reduction potential of HAT-CN was −0.53 V. The LUMO level of HAT-CN which was calculated from the CV measurement was −4.41 eV. Thus, HAT-CN was found to have a low LUMO level. Note that HAT-CN was estimated to have a low HOMO level since a high clear oxidation peak potential was not observed as for the oxidation potential of HAT-CN.

To measure the optical bandgap of HAT-CN, a thin film formed by evaporating HAT-CN over a quartz substrate, and an absorption spectrum was measured. The absorption spectrum was measured using an ultraviolet-visible spectrophotometer (V-550 manufactured by JASCO Corporation).

The absorption band on the lowest energy side (on the longest wavelength side) of the absorption spectrum of HAT-CN was observed at around 340 nm. The absorption edge was calculated from the absorption spectrum, and transition energy was estimated on the assumption of direct transition. As a result, the transition energy corresponding to an optical bandgap of HAT-CN was calculated to be 3.43 eV.

The structures described in this example can be used in appropriate combination with any of the embodiments and the other example.

### Example 2

In this example, examples of fabricating light-emitting elements of embodiments of the present invention (a light-emitting element 1 and a light-emitting element 2) and a comparative light-emitting element (a light-emitting element 3) are described. The structure of each of the light-emitting elements fabricated in this example is the same as that illustrated in FIG. 1. Table 4 shows details of the element structures. In addition, structures and abbreviations of compounds used here are given below.

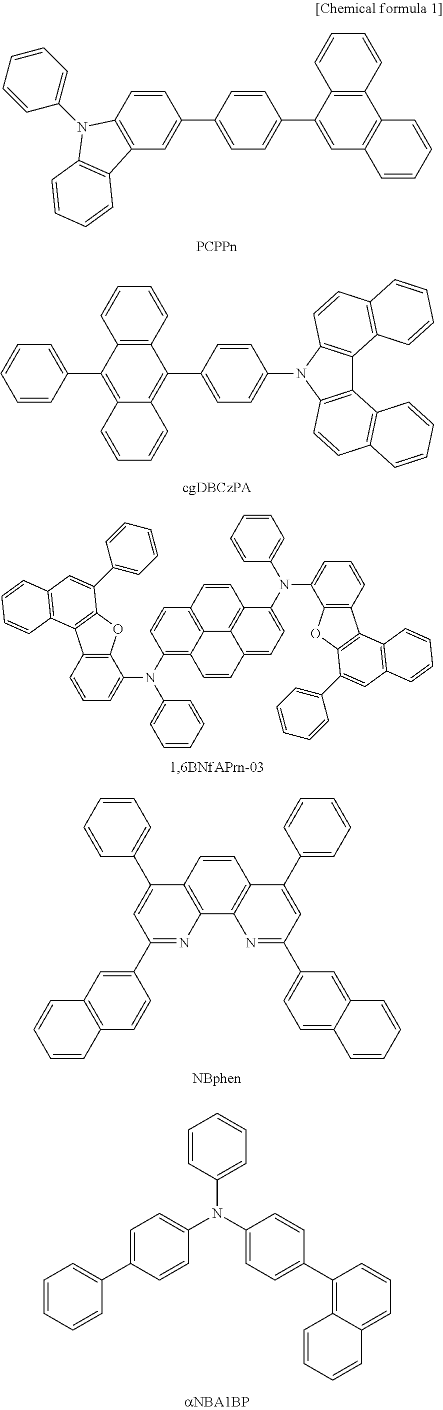 [SMILES: c1ccc(-n2c3ccccc3c3cc(-c4ccc(-c5cc6ccccc6c6ccccc56)cc4)ccc32)cc1 ; c1ccc(-c2c3ccccc3c(-c3ccc(-n4c5ccc6ccccc6c5c5c6ccccc6ccc54)cc3)c3ccccc23)cc1 ; c1ccc(-c2cc3ccccc3c3c2oc2c(N(c4ccccc4)c4ccc5ccc6c(N(c7ccccc7)c7cccc8c7oc7c(-c9ccccc9)cc9ccccc9c78)ccc7ccc4c5c76)cccc23)cc1 ; c1ccc(-c2cc(-c3ccc4ccccc4c3)nc3c2ccc2c(-c4ccccc4)cc(-c4ccc5ccccc5c4)nc23)cc1 ; c1ccc(-c2ccc(N(c3ccccc3)c3ccc(-c4cccc5ccccc45)cc3)cc2)cc1]

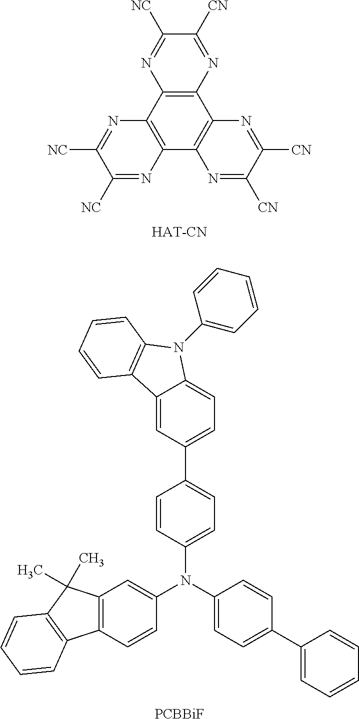

TABLE 4

| | | Reference | Thickness | | Weight |
|---|---|---|---|---|---|
| | Layer | numeral | (nm) | Material | ratio |
| Light- | Electrode | 102(2) | 70 | ITO | — |
| emitting | | 102(1) | 15 | Ag:Mg | 1:0.1*¹⁾ |
| layer 1 | Electron-injection layer | 119 | 1 | LiF | — |
| | Electron-transport layer | 118(2) | 15 | NBPhen | — |
| | | 118(1) | 5 | cgDBCzPA | — |
| | Light-emitting layer | 130 | 25 | cgDBCzPA:1,6BnfAPrn-03 | 1:0.03 |
| | Hole-transport layer | 112(3) | 10 | PCPPn | — |
| | | 112(2) | 5 | αNBA1BP | — |
| | | 112(1) | 5 | PCBBiF | — |
| | Hole-injection layer | 111 | 5 | HAT-CN | — |
| | Electrode | 101b | 10 | IGZO(134) | — |
| | | 101a | 200 | Al—Ni—La | — |
| Light- | Electrode | 102(2) | 70 | ITO | — |
| emitting | | 102(1) | 15 | Ag:Mg | 1:0.1*¹⁾ |
| layer 2 | Electron-injection layer | 119 | 1 | LiF | — |
| | Electron-transport layer | 118(2) | 15 | NBPhen | — |
| | | 118(1) | 5 | cgDBCzPA | — |
| | Light-emitting layer | 130 | 25 | cgDBCzPA:1,6BnfAPrn-03 | 1:0.03 |
| | Hole-transport layer | 112 | 10 | PCPPn | — |
| | Hole-injection layer | 111(2) | 10 | PCPPn:MoO3 | 1:0.5 |
| | | 111(1) | 5 | HAT-CN | — |
| | Electrode | 101b | 10 | IGZO(134) | — |
| | | 101a | 200 | Al—Ni—La | — |
| Light- | Electrode | 102(2) | 70 | ITO | — |
| emitting | | 102(1) | 15 | Ag:Mg | 1:0.1*¹⁾ |
| layer 3 | Electron-injection layer | 119 | 1 | LiF | — |
| | Electron-transport layer | 118(2) | 15 | NBPhen | — |
| | | 118(1) | 5 | cgDBCzPA | — |
| | Light-emitting layer | 130 | 25 | cgDBCzPA:1,6BnfAPm-03 | 1:0.03 |
| | Hole-transport layer | 112 | 10 | PCPPn | — |
| | Hole-injection layer | 111 | 15 | PCPPn:MoO3 | 1:0.5 |
| | Electrode | 101b | 10 | IGZO(134) | — |
| | | 101a | 200 | Al—Ni—La | — |

^{*1)}volume ratio

### <Fabrication of Light-Emitting Elements>

Methods for fabricating light-emitting elements of this example are described below.

### <Fabrication of Light-Emitting Element 1>

As the conductive layer 101a of the electrode 101, an Al—Ni—La film was formed to a thickness of 200 nm over a glass substrate. Next, an In—Ga—Zn oxide film was formed to a thickness of 10 nm as the conductive layer 101b over and in contact with the conductive layer 101a. At this time, the In—Ga—Zn oxide film was formed using a sputtering target in which the atomic ratio of metal elements was In:Ga:Zn=1:3:4 (hereinafter denoted by IGZO(134)). The deposition conditions were as follows: a flow rate of Ar of 45 sccm; a pressure of 0.7 Pa; a power of 0.5 kW; and a substrate temperature of 200° C. Through the above steps, the electrode layer 101 was formed. Note that the area of the electrode 101 was 4 mm² (2 mm×2 mm).

As the hole-injection layer 111, HAT-CN was deposited by evaporation to a thickness of 5 nm over the electrode 101. Note that HAT-CN is an organic acceptor material in the hole-injection layer 111.

As the hole-transport layer 112, PCBBiF was deposited by evaporation to a thickness of 5 nm over the hole-injection layer 111, and 4-(1-naphthyl)-4′-phenytriphenylamine (abbreviation: αNBA1BP) was deposited by evaporation to a thickness of 5 nm, and then, PCPPn was deposited by evaporation to a thickness of 10 nm.

Next, as the light-emitting layer 130, 7-[4-(10-phenyl-9-anthryl)phenyl]-7H-dibenzo[c,g]carbazole (abbreviation: cgDBCzPA) and N,N′-(pyrene-1,6-diyl)bis[(6,N-diphenylbenzo[b]naphtho[1,2-d]furan)-8-amine](abbreviation: 1,6BnfAPrn-03) were deposited over the hole-transport layer 112 by co-evaporation such that the deposited layer has a weight ratio of cgDBCzPA:1,6BnfAPrn-03=1:0.03 and a thickness of 25 nm. In the light-emitting layer 130, cgDBCzPA serves as a host material and 1,6 BnfAPrn-03 serves as a guest material (fluorescent material).

As the electron-transport layer 118, cgDBCzPA and 2,9-bis(naphthalen-2-yl)-4,7-diphenyl-1,10-phenanthroline (abbreviation: NBPhen) were sequentially deposited by evaporation to thicknesses of 5 nm and 15 nm, respectively, over the light-emitting layer 130.

As the electron-injection layer 119, lithium fluoride (LiF) was deposited over the electron-transport layer 118 by evaporation to a thickness of 1 nm.

Next, as the electrode 102, an alloy film of silver (Ag) and magnesium (Mg) was deposited over the electron-injection layer 119 by co-evaporation in a volume ratio of Ag:Mg=1:0.1 to a thickness of 15 nm, and then, an ITO film was formed to a thickness of 70 nm by a sputtering method.

Next, in a glove box containing a nitrogen atmosphere, the light-emitting element 1 was sealed by fixing a glass substrate for sealing to a glass substrate on which the organic materials were deposited using a sealant for an organic EL device. Specifically, after the sealant was applied to surround the organic materials deposited on the glass substrate and these glass substrates were bonded to each other, irradiation with ultraviolet light having a wavelength of 365 nm at 6 J/cm² and heat treatment at 80° C. for one hour were performed. Through the process, the light-emitting element 1 was obtained.

### <Fabrication of Light-Emitting Elements 2 and 3>

The light-emitting elements 2 and 3 were fabricated through the same steps as those for the light-emitting element 1 except for the steps of forming the hole-injection layer 111 and the hole-transport layer 112.

As the hole-injection layer 111 of the light-emitting element 2, HAT-CN was deposited by evaporation to a thickness of 5 nm, and then, PCPPn and molybdenum oxide (MoO₃) were deposited by co-evaporation such that the deposited layer has a weight ratio of PCPPn to MoO₃ of 1:0.5 and a thickness of 10 nm. Note that the hole-injection layer 111 of the light-emitting element 2 includes HAT-CN as the organic acceptor material. As the hole-transport layer 112, PCPPn was deposited over the hole-injection layer 111 by evaporation to a thickness of 10 nm.

As the hole-injection layer 111 of the light-emitting element 3, PCPPn and molybdenum oxide (MoO₃) were deposited by co-evaporation such that the deposited layer has a weight ratio of PCPPn to MoO₃ of 1:0.5 and a thickness of 15 nm. Note that the hole-injection layer 111 of the light-emitting element 3 does not include an organic acceptor material and includes MoO₃ as the acceptor material. As the hole-transport layer 112, PCPPn was deposited over the hole-injection layer 111 by evaporation to a thickness of 10 nm.

### <Characteristics of Light-Emitting Elements>

Next, a substrate over which a blue color filter with a thickness of 0.8 μm was formed as an optical element was stacked over each of the light-emitting elements 1 to 3, and characteristics thereof were measured. For measuring the luminance and the CIE chromaticity, a luminance colorimeter (BM-5A manufactured by TOPCON TECHNOHOUSE CORPORATION) was used. For measuring the electroluminescence spectrum, a multi-channel spectrometer (PMA-11 manufactured by Hamamatsu Photonics K.K.) was used.

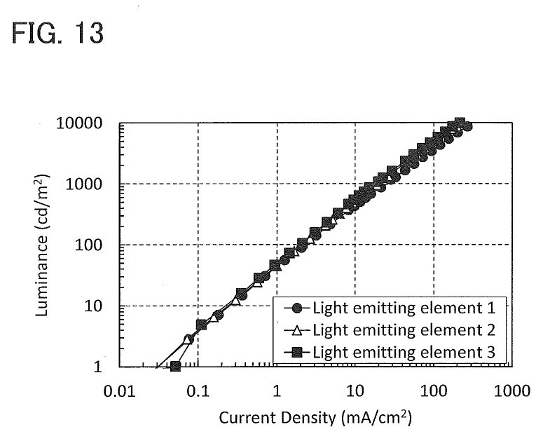

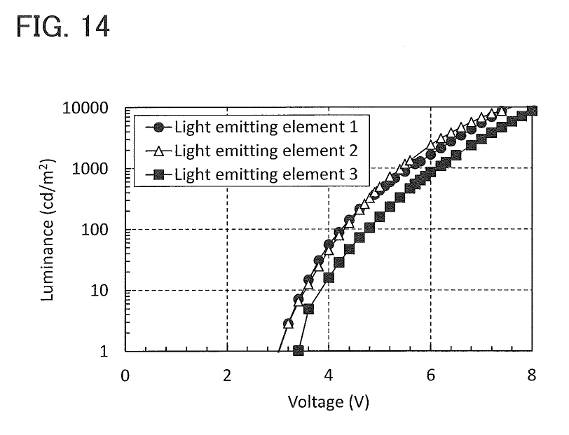

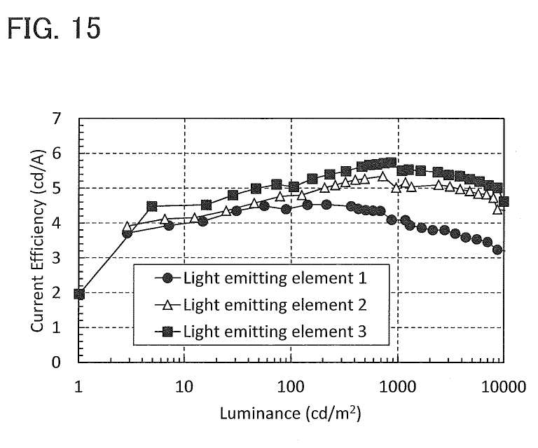

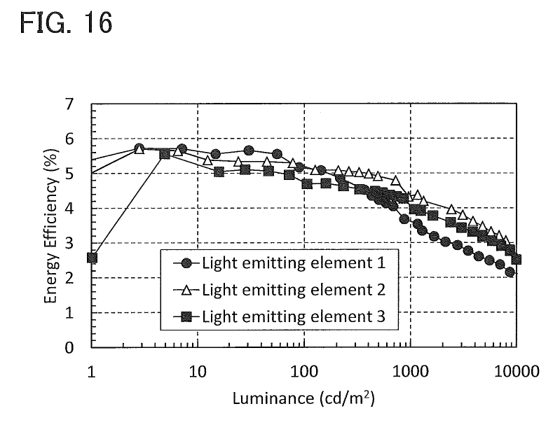

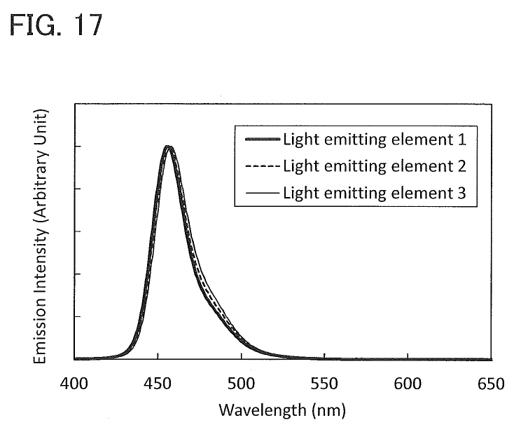

FIG. 13, FIG. 14, FIG. 15, and FIG. 16 show luminance-current density characteristics, luminance-voltage characteristics, current efficiency-luminance characteristics, and energy efficiency-luminance characteristics, respectively, of the light-emitting elements 1 to 3. FIG. 17 shows electroluminescence spectra when a current at a current density of 2.5 mA/cm² was supplied to the light-emitting elements 1 to 3. The measurements of the light-emitting elements were performed at room temperature (in an atmosphere kept at 23° C.). The energy efficiency in this example was calculated by measuring luminance from the front and emission spectra on the assumption of light distribution on a perfectly diffusing surface (also referred to as a Lambertian surface) and using energy of light emission [W]/power consumption [W].

Table 5 shows element characteristics of the light-emitting elements 1 to 3 at around 100 cd/m².

TABLE 5

| | | | | | Current | Energy |
|---|---|---|---|---|---|---|
| | Voltage | Current density | Chromaticity | Luminance | efficiency | efficiency |
| | (V) | (mA/cm²) | (x, y) | (cd/m²) | (cd/A) | (%) |
| Light-emitting | 4.20 | 2.04 | (0.140, 0.049) | 90 | 4.4 | 5.2 |
| element 1 | | | | | | |
| Light-emitting | 4.40 | 2.62 | (0.139, 0.054) | 130 | 4.8 | 5.1 |
| element 2 | | | | | | |
| Light-emitting | 4.80 | 2.10 | (0.138, 0.057) | 110 | 5.0 | 4.7 |
| element 3 | | | | | | |

As shown in FIG. 17 and Table 5, the light-emitting elements 1 to 3 emitted blue light with high color purity. Furthermore, as shown in FIG. 14 and Table 5, the light-emitting elements 1 and 2 are driven at lower voltage than the light-emitting element 3. This indicates that the carrier injection barrier is decreased between the electrode 101 and the hole-injection layer 111 by using an organic acceptor material for the hole-injection layer 111 over and in contact with the conductive layer 101b and a light-emitting element with low drive voltage can be obtained.

On the other hand, as shown in FIG. 15 and Table 5, each of the light-emitting elements 1 and 2 have lower current efficiency than the light-emitting element 3. However, as shown in Table 5, the light-emitting elements 1 and 2 emitted blue light with higher color purity than that of the light-emitting element 3. The luminance and current efficiency are affected by the chromaticity of emitted light, and even in the case where the light-emitting element emits the same amount of photons, when the chromaticity of emitted light is changed, the luminance and the current efficiency are changed. When comparison is made using energy efficiency, which is not affected by the chromaticity of emitted light, the light-emitting elements 1 and 2 are found to have higher energy efficiency than the light-emitting element 3 at around 100 cd/m² as shown in FIG. 16 and Table 5. In other words, the light-emitting elements 1 and 2 of embodiments of the present invention have low power consumption. In the case where the light-emitting elements 1 to 3 that emitted blue light with high color purity and light-emitting elements of green and red are used for pixels in a display device, a blue pixel is used at luminance of around 100 cd/m². Therefore, the light-emitting elements fabricated in this example are light-emitting elements suitable for a display device.

### <Correlation of Energy Levels>

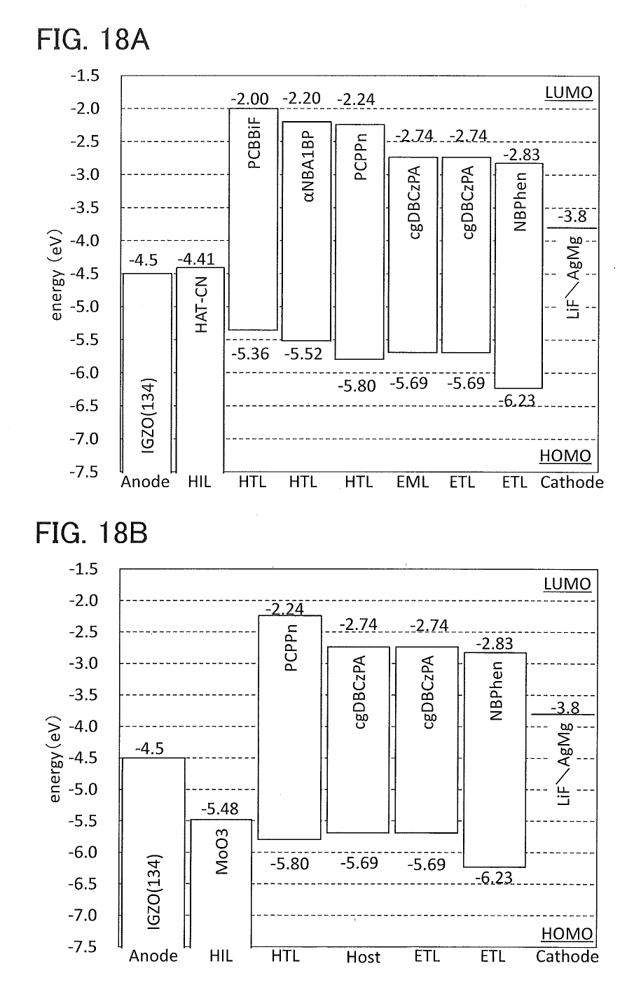

FIGS. 18A and 18B show the work functions of metal and an inorganic material and the LUMO and HOMO levels of the organic compounds contained in the light-emitting elements 1 to 3. The LUMO and HOMO levels of the organic compounds are estimated from CV measurement, and the CV measurement was performed in the same manner as that in Example 1. The measurement method of the work function of IGZO(134) is the same as that in Example 1. The work functions of the metal and the inorganic material were measured by photoelectron spectroscopy using “AC-2” manufactured by Riken Keiki Co., Ltd. in the air. Note that the difference between the vacuum level and the Fermi level is referred to as a work function. Furthermore, IGZO(134) and MoO₃ are assumed to be in a degenerate state, and the Fermi level and the energy level of the conduction band minimum are substantially equal.

FIG. 18A shows a correlation of energy levels of the light-emitting element 1, and FIG. 18B shows a correlation of energy levels of the light-emitting element 3. In FIGS. 18A and 18B, HIL, HTL, EML, ETL, Anode, and Cathode represent the hole-injection layer, the hole-transport layer, the light-emitting layer, the electron-transport layer, the anode, and the cathode, respectively, and show energy levels of materials for layers.

As shown in FIG. 18A, in the light-emitting element 1, the difference between the LUMO level of HAT-CN of the hole-injection layer 111 and the HOMO level of PCBBiF of the hole-transport layer 112 is small (i.e., 1 eV or less); thus, when charge separation is caused between HAT-CN which is an organic acceptor material and PCBBiF which is a hole transport material, electrons and holes are generated. Furthermore, the difference between the Fermi level of IGZO(134) of the conductive layer 101b and the LUMO level of HAT-CN of the hole-injection layer 111 is small (i.e., 0.1 eV or less). Thus, electrons are easily injected from the hole-injection layer 111 to the conductive layer 101b. Furthermore, the differences in HOMO levels between PCBBiF, αNBA1BP, and PCPPn of the hole-transport layer 112 are each 0.5 eV or less, and holes can be smoothly transported to each compound. Accordingly, the light-emitting element 1 is a light-emitting element with low drive voltage.

Meanwhile, the light-emitting element 3 includes MoO₃ instead of HAT-CN which is an organic acceptor material for the hole-injection layer 111. MoO₃ is an acceptor material with a low energy level of the conduction band minimum, and has a function of generating electrons and holes by charge separation between the MoO₃ and the hole-transport material. As shown in FIG. 18B, the difference between the Fermi level of MoO₃ of the hole-injection layer 111 and the HOMO level of PCPPn is small. Accordingly, when charge separation is caused between MoO₃ and PCPPn, electrons and holes can be generated. However, since the difference between the Fermi level of MoO₃ of the hole-injection layer 111 and the Fermi level of IGZO(134) of the conductive layer 101b is large, an energy barrier is formed when electrons are injected from the hole-injection layer 111 to the conductive layer 101b. Thus, the drive voltage of the light-emitting element 3 is increased.

Note that the light-emitting element 2 includes MoO₃ in addition to HAT-CN which is the organic acceptor material for the hole-injection layer 111. The light-emitting element 2 has a smaller number of hole-transport layers than the light-emitting element 1, and is driven at low drive voltage which is substantially equal to that of the light-emitting element 1 and has higher current efficiency and higher energy efficiency than the light-emitting element 1. In other words, as in the light-emitting element 2 which is one embodiment of the present invention, it is preferable that the hole-injection layer 111 include an organic acceptor material and further include another acceptor material.

As described above, with the structure of one embodiment of the present invention, a light-emitting element with low drive voltage and low power consumption can be provided.

The structures described in this example can be used in appropriate combination with any of the embodiments and the other example.

This application is based on Japanese Patent Application serial no. 2016-086490 filed with Japan Patent Office on Apr. 22, 2016, the entire contents of which are hereby incorporated by reference.

What is claimed is:

1. A light-emitting element comprising:
a first electrode;
a second electrode; and
an EL layer located between the first electrode and the second electrode,
wherein the first electrode comprises a first conductive layer and a second conductive layer comprising a region in contact with the first conductive layer,
wherein the first conductive layer is configured to reflect light,
wherein the second conductive layer is configured to transmit light,
wherein the second conductive layer comprises an oxide comprising In and M,
wherein the M represents one or more of Al, Si, Ti, Ga, Y, Zr, La, Ce, Nd, and Hf, and
wherein the EL layer comprises an organic acceptor material in a first region in contact with the second conductive layer.

2. The light-emitting element according to claim 1, wherein the EL layer comprises an acceptor material different from the organic acceptor material in a second region in contact with the first region.

3. The light-emitting element according to claim 1, wherein the EL layer comprises a hole-transport material in a second region in contact with the first region.

4. The light-emitting element according to claim 3, wherein the second region further comprises an acceptor material different from the organic acceptor material.

5. The light-emitting element according to claim 1, wherein the organic acceptor material comprises an azatriphenylene skeleton.

6. The light-emitting element according to claim 5, wherein the organic acceptor material comprises 2,3,6,7,10,11-hexacyano-1,4,5,8,9,12-hexaazatriphenylene.

7. The light-emitting element according to claim 1, wherein the organic acceptor material comprises a cyano group.

8. The light-emitting element according to claim 1, wherein a content of the M is higher than or equal to a content of the In in the oxide.

9. The light-emitting element according to claim 1, wherein the oxide comprises In, Ga, and Zn.

10. The light-emitting element according to claim 1, wherein the first conductive layer comprises Al or Ag.

11. A display device comprising:
the light-emitting element according to claim 1; and
a transistor electrically connected to the first electrode or the second electrode,
wherein the transistor comprises an oxide semiconductor layer in a channel region,
wherein the oxide semiconductor layer comprises In and M, and
wherein the M represents one or more of Al, Si, Ti, Ga, Y, Zr, La, Ce, Nd, and Hf.

12. A light-emitting element comprising:
a first electrode;
a second electrode; and
an EL layer located between the first electrode and the second electrode,
wherein the first electrode comprises a first conductive layer and a second conductive layer comprising a region in contact with the first conductive layer,
wherein the first conductive layer is configured to reflect light,
wherein the second conductive layer is configured to transmit light,
wherein the second conductive layer comprises an oxide comprising In and M,
wherein the M represents one or more of Al, Si, Ti, Ga, Y, Zr, La, Ce, Nd, and Hf,
wherein the EL layer comprises an organic acceptor material in a first region in contact with the second conductive layer, and
wherein a difference between an energy level of a conduction band minimum of the oxide and an energy level of LUMO of the organic acceptor material is greater than or equal to 0 eV and less than or equal to 0.5 eV.

13. The light-emitting element according to claim 12, wherein the EL layer comprises an acceptor material different from the organic acceptor material in a second region in contact with the first region.

14. The light-emitting element according to claim 12, wherein the EL layer comprises a hole-transport material in a second region in contact with the first region.

15. The light-emitting element according to claim 14, wherein the second region further comprises an acceptor material different from the organic acceptor material.

16. The light-emitting element according to claim 12, wherein the organic acceptor material comprises an azatriphenylene skeleton.

17. The light-emitting element according to claim 12, wherein the organic acceptor material comprises 2,3,6,7,10,11-hexacyano-1,4,5,8,9,12-hexaazatriphenylene.

18. The light-emitting element according to claim 12, wherein the organic acceptor material comprises a cyano group.

19. The light-emitting element according to claim 12, wherein a content of the M is higher than or equal to a content of the In in the oxide.

20. The light-emitting element according to claim 12, wherein the oxide comprises In, Ga, and Zn.

21. The light-emitting element according to claim 12, wherein the first conductive layer comprises Al or Ag.

22. A display device comprising:
the light-emitting element according to claim 12; and
a transistor electrically connected to the first electrode or the second electrode,
wherein the transistor comprises an oxide semiconductor layer in a channel region,
wherein the oxide semiconductor layer comprises In and M, and
wherein the M represents one or more of Al, Si, Ti, Ga, Y, Zr, La, Ce, Nd, and Hf.
